(19) United States
(12) Patent Application Publication
(10) Pub. No.: US 2023/0283048 A1
(43) Pub. Date: Sep. 7, 2023

(54) SURFACE EMITTING LASER APPARATUS, ELECTRONIC DEVICE, AND METHOD FOR MANUFACTURING SURFACE EMITTING LASER APPARATUS

(71) Applicant: SONY SEMICONDUCTOR SOLUTIONS CORPORATION, KANAGAWA (JP)

(72) Inventor: JUGO MITOMO, KUMAMOTO (JP)

(21) Appl. No.: 17/999,279

(22) PCT Filed: Apr. 12, 2021
(86) PCT No.: PCT/JP2021/015166

§ 371 Date: Nov. 18, 2022

(30) Foreign Application Priority Data
May 29, 2020 (JP) 2020-094388

(51) Int. Cl. H01S 5/183; H01S 5/042; H01S 5/42; H01S 5/343

(52) U.S. Cl. CPC H01S 5/18313; H01S 5/04256; H01S 5/423; H01S 5/34353; H01S 5/18361; H01S 5/18305

(57) ABSTRACT

Provided is a surface emitting laser apparatus capable of improving the yield.

The present technology includes: a stacked structure having at least one light emission unit including a first oxidized constriction layer and an electrode unit including a second oxidized constriction layer at different positions in an in-plane direction; and a conductive layer that makes the light emission unit and the electrode unit conductive with each other, in which the conductive layer includes a first portion covering a region between the light emission unit and the electrode unit, a second portion covering a near half part of the electrode unit, the near half part being relatively close to the light emission unit, and a third portion covering a far half part of the electrode unit, the far half part being relatively far from the light emission unit, in the stacked structure, and a degassing unit is provided in the first portion and/or the second portion and the third portion.

### TECHNICAL FIELD

A technology according to the present disclosure (hereinafter, also referred to as “the present technology”) relates to a surface emitting laser apparatus, an electronic device, and a method for manufacturing the surface emitting laser apparatus.

### BACKGROUND ART

There is known a conventional surface emitting laser apparatus including: a stacked structure having a light emission unit including a first oxidized constriction layer and a pad forming region including a second oxidized constriction layer at different positions in an in-plane direction; and a conductive layer that makes the light emission unit and the pad forming region conductive with each other (see, for example, Patent Document 1).

### CITATION LIST

### Patent Document

Patent Document 1: Japanese Patent Application Laid-Open No. 2007-173513

### SUMMARY OF THE INVENTION

### Problems to be Solved by the Invention

However, the conventional surface emitting laser apparatus has room for improvement in terms of improving the yield.

Therefore, a main object of the present technology is to provide a surface emitting laser apparatus capable of improving the yield.

### Solutions to Problems

The present technology provides a surface emitting laser apparatus including:
a stacked structure having at least one light emission unit including a first oxidized constriction layer and an electrode unit including a second oxidized constriction layer at different positions in an in-plane direction; and
a conductive layer that makes the light emission unit and the electrode unit conductive with each other,
in which the conductive layer includes
a first portion covering a region between the light emission unit and the electrode unit,
a second portion covering a near half part of the electrode unit, the near half part being relatively close to the light emission unit, and
a third portion covering a far half part of the electrode unit, the far half part being relatively far from the light emission unit, in the stacked structure, and
a degassing unit is provided in the first portion and/or the second portion and the third portion.

The degassing unit may be an opening, a notch, or a thin film.

The surface emitting laser apparatus may further include an insulating layer arranged between the first portion and the stacked structure and/or between the second portion and the near half part and between the third portion and the far half part.

The thickness of the insulating layer may be equal to or greater than 0.1 μm and equal to or less than 2.0 μm.

The degassing unit may be provided at least in a part of the second portion covering a side surface of the near half part and/or a part of the third portion covering a side surface of the far half part.

The degassing unit may be provided at least in a position in a part of the second portion covering a side surface of the near half part and/or a part of the third portion covering a side surface of the far half part, the position corresponding to an outer circumferential surface of the second oxidized constriction layer.

The degassing unit may be provided at least in a part of the second portion covering an upper surface of the near half part and/or a part of the third portion covering an upper surface of the far half part.

The degassing unit may be provided at least in a part of the second portion covering an outer circumferential part of the upper surface of the near half part and/or a part of the third portion covering an outer circumferential part of the upper surface of the far half part.

The degassing unit may be provided at least in a part of the second portion covering a corner part formed between the upper surface and the side surface of the near half part and/or a part of the third portion covering a corner part formed between the upper surface and the side surface of the far half part.

The degassing unit may be provided at least at a boundary between the first portion and the second portion.

At least a part of the degassing unit may be provided in a position within 35 μm from an oxidized region of the second oxidized constriction layer in the conductive layer.

The at least one light emission unit may be a plurality of light emission units, and the conductive layer may make each of at least two light emission units among the plurality of light emission units and the electrode unit conductive with each other.

The conductive layer may cover a region between each of the plurality of light emission units and the electrode unit and an outer circumferential surface and an outer circumferential part of an upper surface of the electrode unit in the stacked structure.

A central interval between two adjacent light emission units among the plurality of light emission units may be equal to or less than 35 μm.

The light emission unit may include a first multilayer film reflecting mirror including the first oxidized constriction layer therein, a second multilayer film reflecting mirror, and an active layer arranged between the first and second multilayer film reflecting mirrors, and the electrode unit may include a first multilayer film reflecting mirror including the second oxidized constriction layer therein, a second multilayer film reflecting mirror, and an active layer arranged between the first and second multilayer film reflecting mirrors.

The light emission unit may include a substrate that is arranged on a side opposite to a side of the active layer with respect to the first multilayer film reflecting mirror and that is transparent to an oscillation wavelength of the light emission unit, and the light emission unit may emit light to a back surface side of the substrate.

The present technology also provides an electronic device including the surface emitting laser apparatus.

The present technology also provides a method for manufacturing a surface emitting laser apparatus, the method including:
a step of forming a stacked body by stacking a first multilayer film reflecting mirror including a selected oxidized layer therein, an active layer, and a second multilayer film reflecting mirror in this order on a substrate;
a step of etching the stacked body to form a first mesa including one part of the selected oxidized layer and a second mesa including another part of the selected oxidized layer;
a step of oxidizing the one part and the another part of the selected oxidized layer from side surfaces to form a stacked structure having a light emission unit including a first oxidized constriction layer and an electrode unit including a second oxidized constriction layer; and
a step of forming a conductive layer including a first portion covering a region between the light emission unit and the electrode unit of the stacked structure, a second portion covering a near half part of the electrode unit, the near half part being relatively close to the light emission unit, and a third portion covering a far half part of the electrode unit, the far half part being relatively far from the light emission unit,
in which,
in the step of forming the conductive layer,
a degassing unit is formed in the first portion and/or the second portion and the third portion.

The degassing unit may be an opening, a notch, or a thin film.

The method for manufacturing the surface emitting laser apparatus may further include, after the step of forming the stacked structure and before the step of forming the conductive layer, a step of forming an insulating layer in a region between the light emission unit and the electrode unit and/or in the near half part and the far half part of the stacked structure.

### BRIEF DESCRIPTION OF DRAWINGS

FIG. 1 is a plan view of a surface emitting laser apparatus according to a first example of an embodiment of the present technology.

FIG. 2 is a cross-sectional view taken along line A-A of FIG. 1.

FIG. 3 is a cross-sectional view taken along line B-B of FIG. 1.

FIG. 4 is a cross-sectional view taken along line C-C of FIG. 1.

FIG. 5 is a flowchart for explaining a method for manufacturing the surface emitting laser apparatus according to the first example of an embodiment of the present technology.

FIG. 6 is a cross-sectional view (part 1) of each step of the method for manufacturing the surface emitting laser apparatus according to the first example of an embodiment of the present technology.

FIG. 7 is a cross-sectional view (part 2) of each step of the method for manufacturing the surface emitting laser apparatus according to the first example of an embodiment of the present technology.

FIG. 8 is a cross-sectional view (part 3) of each step of the method for manufacturing the surface emitting laser apparatus according to the first example of an embodiment of the present technology.

FIG. 9 is a cross-sectional view (part 4) of each step of the method for manufacturing the surface emitting laser apparatus according to the first example of an embodiment of the present technology.

FIG. 10 is a cross-sectional view (part 5) of each step of the method for manufacturing the surface emitting laser apparatus according to the first example of an embodiment of the present technology.

FIG. 11 is a cross-sectional view (part 6) of each step of the method for manufacturing the surface emitting laser apparatus according to the first example of an embodiment of the present technology.

FIG. 12 is a cross-sectional view (part 7) of each step of the method for manufacturing the surface emitting laser apparatus according to the first example of an embodiment of the present technology.

FIG. 13 is a cross-sectional view (part 8) of each step of the method for manufacturing the surface emitting laser apparatus according to the first example of an embodiment of the present technology.

FIG. 14 is a plan view of a surface emitting laser apparatus according to a second example of an embodiment of the present technology.

FIG. 15 is a cross-sectional view taken along line A-A of FIG. 14.

FIG. 16 is a cross-sectional view taken along line B-B of FIG. 14.

FIG. 17 is a plan view of a surface emitting laser apparatus according to a third example of an embodiment of the present technology.

FIG. 18 is a cross-sectional view taken along line A-A of FIG. 17.

FIG. 19 is a cross-sectional view taken along line B-B of FIG. 17.

FIG. 20 is a plan view of a surface emitting laser apparatus according to a fourth example of an embodiment of the present technology.

FIG. 21 is a cross-sectional view taken along line A-A of FIG. 20.

FIG. 22 is a cross-sectional view taken along line B-B of FIG. 20.

FIG. 23 is a plan view of a surface emitting laser apparatus according to a fifth example of an embodiment of the present technology.

FIG. 24 is a cross-sectional view taken along line A-A of FIG. 23.

FIG. 25 is a cross-sectional view taken along line B-B of FIG. 23.

FIG. 26 is a plan view of a surface emitting laser apparatus according to a sixth example of an embodiment of the present technology.

FIG. 27 is a cross-sectional view taken along line A-A of FIG. 26.

FIG. 28 is a cross-sectional view taken along line B-B of FIG. 26.

FIG. 29 is a plan view of a surface emitting laser apparatus according to a seventh example of an embodiment of the present technology.

FIG. 30 is a cross-sectional view taken along line A-A of FIG. 29.

FIG. 31 is a cross-sectional view taken along line B-B of FIG. 29.

FIG. 32 is a plan view of a surface emitting laser apparatus according to an eighth example of an embodiment of the present technology.

FIG. 33 is a cross-sectional view taken along line A-A of FIG. 32.

FIG. 34 is a cross-sectional view taken along line B-B of FIG. 32.

FIG. 35 is a plan view of a surface emitting laser apparatus according to a ninth example of an embodiment of the present technology.

FIG. 36 is a cross-sectional view taken along line A-A of FIG. 35.

FIG. 37 is a cross-sectional view taken along line B-B of FIG. 35.

FIG. 38 is a plan view of a surface emitting laser apparatus according to a tenth example of an embodiment of the present technology.

FIG. 39 is a cross-sectional view taken along line A-A of FIG. 38.

FIG. 40 is a cross-sectional view taken along line B-B of FIG. 38.

FIG. 41 is a cross-sectional view of a surface emitting laser apparatus according to a first modification of an embodiment of the present technology.

FIG. 42 is a cross-sectional view of a surface emitting laser apparatus according to a second modification of an embodiment of the present technology.

FIG. 43 is a cross-sectional view of a surface emitting laser apparatus according to a third modification of an embodiment of the present technology.

FIG. 44 is a cross-sectional view of a surface emitting laser apparatus according to a fourth modification of an embodiment of the present technology.

FIG. 45 is a cross-sectional view of a surface emitting laser apparatus according to a fifth modification of an embodiment of the present technology.

FIG. 46 is a cross-sectional view of a surface emitting laser apparatus according to a sixth modification of an embodiment of the present technology.

FIG. 47 is a cross-sectional view of a surface emitting laser apparatus according to a seventh modification of an embodiment of the present technology.

FIG. 48 is a cross-sectional view of a surface emitting laser apparatus according to an eighth modification of an embodiment of the present technology.

FIG. 49 is a cross-sectional view of a surface emitting laser apparatus according to a ninth modification of an embodiment of the present technology.

FIG. 50 is a cross-sectional view of a surface emitting laser apparatus according to a tenth modification of an embodiment of the present technology.

FIG. 51 is a view showing an application example of the surface emitting laser apparatus according to each example and each modification of an embodiment of the present technology to a distance measuring device.

FIG. 52 is a block diagram showing an example of a schematic configuration of a vehicle control system.

FIG. 53 is an explanatory diagram showing an example of an installation position of a distance measuring device.

### MODE FOR CARRYING OUT THE INVENTION

Preferred embodiments of the present technology will be described in detail below with reference to the accompanying drawings. Note that, in the present specification and the drawings, the same reference numerals are given to the constituent elements having substantially the same functional configuration, and redundant explanations are omitted. The embodiments described below are typical embodiments of the present technology, and the scope of the present technology should not be construed narrowly. In the present specification, even in a case where it is indicated that each of the surface emitting laser apparatus, the electronic device, and the method for manufacturing the surface emitting laser apparatus according to the present technology exhibits a plurality of effects, it is sufficient that each of the surface emitting laser apparatus, the electronic device, and the method for manufacturing the surface emitting laser apparatus according to the present technology exhibit at least one effect. The effects described in the present specification are merely examples and are not intended to be limiting, and other effects may be provided.

Furthermore, explanation will be given in the following order.
1. Configuration of surface emitting laser apparatus according to first example of embodiment of the present technology
2. Operation of surface emitting laser apparatus according to first example of embodiment of the present technology
3. Method for manufacturing surface emitting laser apparatus according to first example of embodiment of the present technology
4. Action of surface emitting laser apparatus according to first example of embodiment of the present technology
5. Effects of surface emitting laser apparatus according to first example of embodiment of the present technology and effects of method for manufacturing the surface emitting laser apparatus
6. Surface emitting laser apparatuses according to second to tenth examples of embodiment of the present technology
7. Surface emitting laser apparatuses according to first to tenth modifications of embodiment of the present technology
8. Another modification of embodiment of the present technology
9. Example in which surface emitting laser apparatus is applied to distance measuring device
10. Example in which distance measuring device is mounted on moving body

### 1. <Configuration of Surface Emitting Laser Apparatus According to First Example of Embodiment of the Present Technology>

(Overall Configuration)

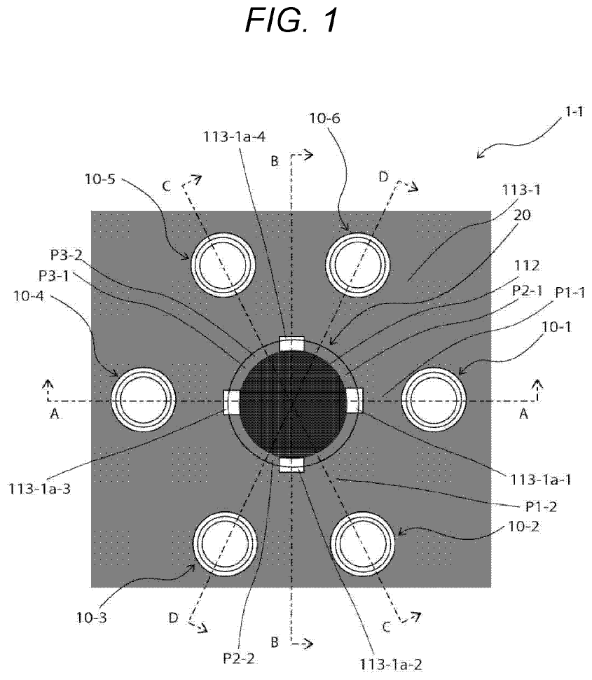

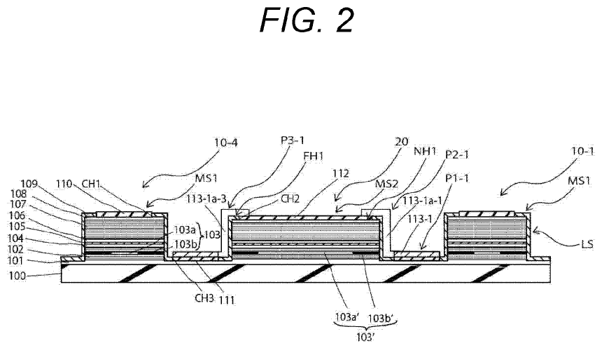

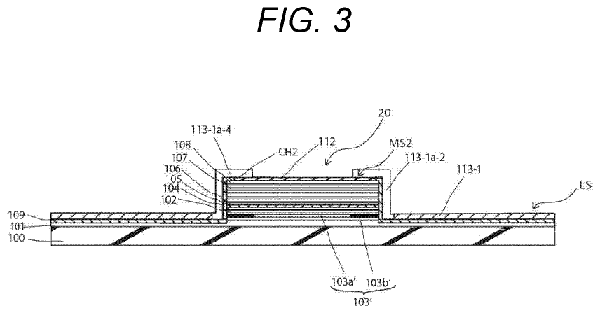

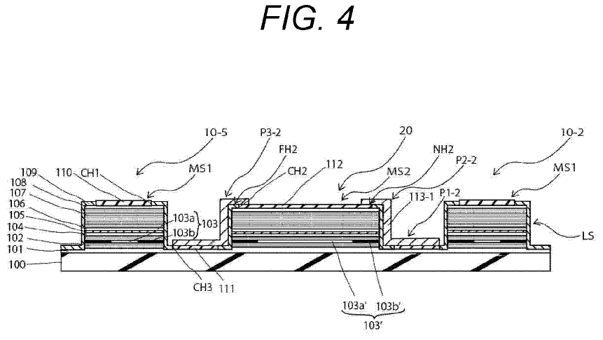

FIG. 1 is a plan view of a surface emitting laser apparatus 1-1 according to a first example of an embodiment of the present technology. FIG. 2 is a cross-sectional view taken along line A-A of FIG. 1. FIG. 3 is a cross-sectional view taken along line B-B of FIG. 1. FIG. 4 is a cross-sectional view taken along line C-C of FIG. 1. The cross section taken along line D-D in FIG. 1 is similar to the cross section taken along line C-C in FIG. 1.

Note that the surface emitting laser apparatuses according to each embodiment and each modification of an embodiment of the present technology described below are collectively referred to as a “surface emitting laser apparatus 1”.

As illustrated in FIG. 1, the surface emitting laser apparatus 1-1 includes: a plurality of (for example, six) light emission units 10 (10-1 to 10-6); an electrode unit 20; and a conductive layer 113-1 that makes the plurality of light emission units 10 and the electrode unit 20 conductive (be electrically connected) with each other.

Each of the light emission units 10 and the electrode unit 20 has a mesa structure (see FIGS. 2 to 4).

As an example, the electrode unit 20 is a common electrode unit common to the plurality of light emission units 10. Although only one combination of the plurality of light emission units 10 and the electrode unit 20 is illustrated in FIG. 1, the surface emitting laser apparatus 1-1 may have a plurality of sets of this combination.

As an example, the plurality of light emission units 10 is arranged so as to surround the electrode unit 20. The plurality of light emission units 10 and the electrode unit 20 have, for example, a substantially circular outer shape in plan view. As an example, each of the light emission units 10 are arranged such that the centers thereof are located at different vertexes of a regular hexagon centered on the center of the electrode unit 20.

As illustrated in FIGS. 2 to 4, the surface emitting laser apparatus 1-1 has a stacked structure LS.

In the stacked structure LS, a first contact layer 101, a first multilayer film reflecting mirror 102, a first spacer layer 104, an active layer 105, a second spacer layer 106, a second multilayer film reflecting mirror 107, a second contact layer 108, and an electrode are stacked in this order on a substrate 100. An oxidized constriction layer (first or second oxidized constriction layer 103, 103′) is arranged inside the first multilayer film reflecting mirror 102.

That is, the stacked structure LS includes the first multilayer film reflecting mirror 102 including the oxidized constriction layer therein, the second multilayer film reflecting mirror 107, and the active layer 105 arranged between the first and second multilayer film reflecting mirrors 102, 107.

Each light emission unit 10 constitutes a part of the stacked structure LS in the in-plane direction (a direction orthogonal to a stacked direction, the same applies hereinafter). The electrode unit 20 constitutes the other part of the stacked structure LS in the in-plane direction.

Each light emission unit 10 has a mesa structure MS1 including the first oxidized constriction layer 103. The electrode unit 20 has a mesa structure MS2 including the second oxidized constriction layer 103′.

That is, the stacked structure LS has the plurality of light emission units 10 having the mesa structure MS1 including the first oxidized constriction layer 103 and the electrode unit 20 including the second oxidized constriction layer 103′ at different positions in the in-plane direction.

As an example, the first and second oxidized constriction layers 103, 103′ are substantially coplanar (in a plane orthogonal to the stacked direction of the stacked structure LS).

In detail, the light emission unit 10 includes the first multilayer film reflecting mirror 102 including the first oxidized constriction layer 103 therein, the second multilayer film reflecting mirror 107, and the active layer 105 arranged between the first and second multilayer film reflecting mirrors 102, 107.

The electrode unit 20 includes the first multilayer film reflecting mirror 102 including the second oxidized constriction layer 103′ therein, the second multilayer film reflecting mirror 107, and the active layer 105 arranged between the first and second multilayer film reflecting mirrors 102, 107.

The mesa structure MS1 functions as a laser resonator in the light emission unit 10. That is, the light emission unit 10 is a surface emitting laser (VCSEL).

Each mesa structure has, for example, a substantially cylindrical shape in plan view, but may have another columnar shape such as a polygonal columnar shape.

The central interval between two adjacent light emission units 10 among the plurality of light emission units 10 is preferably equal to or less than 35 μm, and more preferably equal to or less than 20 μm.

The electrode unit 20 is electrically connected to a laser driver including a driver IC, and a current is supplied from the laser driver.

The stacked structure LS is covered with the insulating layer 109 except for a region where the electrode is arranged. The insulating layer 109 is made of, for example, SiO₂, SiN, or SiON.

A contact hole CH1 for leading the electrode is formed in the insulating layer 109 covering the top of the mesa structure MS1. In the contact hole CH1, the cathode electrode 110 is arranged so as to be in contact with the second contact layer 108 of the mesa structure MS1.

A contact hole CH2 for leading the electrode is formed in the insulating layer 109 covering the top of the mesa structure MS2. In the contact hole CH2, the electrode 112 is arranged so as to be in contact with the second contact layer 108 of the mesa structure MS2.

As an example, the substrate 100 is a GaAs substrate of the first conductivity type.

The substrate 100 is arranged on the side opposite to the active layer 105 side with respect to the first multilayer film reflecting mirror 102. The substrate 100 is transparent to the oscillation wavelength of the light emission unit 10.

As an example, the first contact layer 101 is made of a GaAs-based compound semiconductor of the first conductivity type. The first contact layer 101 is shared by the plurality of light emission units 10 and the electrode unit 20.

A contact hole CH3 for leading the electrode is formed in the insulating layer 109 covering a portion between the mesa structure MS1 and the mesa structure MS2 adjacent to each other in the stacked structure LS. In the contact hole CH3, the anode electrode 111 is arranged so as to be in contact with the first contact layer 101.

The anode electrode 111 is electrically connected to the electrode 112 provided in the top of the mesa structure MS2 via the conductive layer 113-1.

The conductive layer 113-1 is made of metal plating such as gold plating, silver plating, or copper plating. Details of the conductive layer 113-1 will be described later.

The anode electrode 111 may have a single layer structure or a stacked structure.

The anode electrode 111 is made of, for example, at least one metal (including an alloy) selected from the group consisting of Au, Ag, Pd, Pt, Ni, Ti, V, W, Cr, Al, Cu, Zn, Sn, and In.

In a case where the anode electrode 111 has a stacked structure, the anode electrode is made of a material such as Ti/Au, Ti/Al, Ti/Al/Au, Ti/Pt/Au, Ni/Au, Ni/Au/Pt, Ni/Pt, Pd/Pt, or Ag/Pd.

As an example, the first multilayer film reflecting mirror 102 is a semiconductor multilayer film reflecting mirror. The multilayer film reflecting mirror is also referred to as a distributed Bragg reflector. A semiconductor multilayer film reflecting mirror which is a type of multilayer film reflecting mirror (distributed Bragg reflecting mirror) has low light absorption, high reflectance, and conductivity. The first multilayer film reflecting mirror 102 is also referred to as a lower DBR.

As an example, the first multilayer film reflecting mirror 102 is a semiconductor multilayer film reflecting mirror of the first conductivity type, and has a structure in which a plurality of types (for example, two types) of semiconductor layers (refractive index layers) having different refractive indexes is alternately stacked with an optical thickness of ¼(λ/4) of an oscillation wavelength λ. Each refractive index layer of the first multilayer film reflecting mirror 102 is made of, for example, a first conductivity type AlGaAs-based compound semiconductor.

The first oxidized constriction layer 103 is arranged inside the first multilayer film reflecting mirror 102 of the light emission unit 10. As an example, the first oxidized constriction layer 103 includes a non-oxidized region 103a made of AlAs and an oxidized region 103b made of an oxide of AlAs (for example, Al₂O₃) surrounding the non-oxidized region 103a.

The second oxidized constriction layer 103′ is arranged inside the first multilayer film reflecting mirror 102 of the electrode unit 20. As an example, the second oxidized constriction layer 103′ includes a non-oxidized region 103a′ made of AlAs and an oxidized region 103b′ made of an oxide of AlAs (for example, Al₂O₃) surrounding the non-oxidized region 103a′.

The first spacer layer 104 is made of an AlGaAs-based compound semiconductor of the first conductivity type. The “spacer layer” is also referred to as a “cladding layer”.

The active layer 105 has a quantum well structure including a barrier layer made of, for example, an AlGaAs-based compound semiconductor and a quantum well layer. This quantum well structure may be a single quantum well structure (QW structure) or a multiple quantum well structure (MQW structure).

The second spacer layer 106 (upper spacer layer) is made of a second conductivity type AlGaAs-based compound semiconductor. The “spacer layer” is also referred to as a “cladding layer”.

As an example, the second multilayer film reflecting mirror 107 is a semiconductor multilayer film reflecting mirror of the second conductivity type, and has a structure in which a plurality of types (for example, two types) of semiconductor layers (refractive index layers) having different refractive indexes is alternately stacked with an optical thickness of a wavelength of ¼ of an oscillation wavelength. Each refractive index layer of the second multilayer film reflecting mirror 107 is made of, for example, a second conductivity type AlGaAs-based compound semiconductor.

For example, the second contact layer 108 is made of a GaAs-based compound semiconductor of the second conductivity type.

The cathode electrode 110 may have a single layer structure or a stacked structure.

The cathode electrode 110 is made of, for example, at least one metal (including an alloy) selected from the group consisting of Au, Ag, Pd, Pt, Ni, Ti, V, W, Cr, Al, Cu, Zn, Sn, and In.

In a case where the cathode electrode 110 has a stacked structure, the anode electrode is made of a material such as Ti/Au, Ti/Al, Ti/Al/Au, Ti/Pt/Au, Ni/Au, Ni/Au/Pt, Ni/Pt, Pd/Pt, or Ag/Pd.

The electrode 112 may have a single layer structure or a stacked structure.

The electrode 112 is made of, for example, at least one metal (including an alloy) selected from the group consisting of Au, Ag, Pd, Pt, Ni, Ti, V, W, Cr, Al, Cu, Zn, Sn, and In.

In a case where the electrode 112 has a stacked structure, the anode electrode is made of a material such as Ti/Au, Ti/Al, Ti/Al/Au, Ti/Pt/Au, Ni/Au, Ni/Au/Pt, Ni/Pt, Pd/Pt, or Ag/Pd.

(Conductive Layer) The conductive layer 113-1 makes each of the plurality of (for example, six) light emission units 10-1 and the electrode unit 20 conductive with each other.

As an example, as illustrated in FIGS. 2 to 4, the conductive layer 113-1 covers a region between each of the plurality of light emission units 10-1 and the electrode unit 20 and the outer circumferential surface and the outer circumferential part of the upper surface of the electrode unit 20 in the stacked structure LS.

More specifically, the conductive layer 113-1 has a first portion P1 that covers a region between each light emission unit 10 and the electrode unit 20 of the stacked structure LS, a second portion P2 that covers a near half part NH relatively close to the light emission unit 10 of the electrode unit 20, and a third portion P3 that covers a far half part FH relatively far from the light emission unit 10 of the electrode unit 20.

As an example, in the conductive layer 113-1, the first to third portions P1 to P3 are a series.

For example, in FIGS. 1 and 2, the first portion P1 covering a region between the light emission unit 10-1 and the electrode unit 20 of the conductive layer 113-1 is a first portion P1-1.

For example, in FIGS. 1 and 2, the second portion P2 covering the near half part NH1 of the conductive layer 113-1 relatively close to the light emission unit 10-1 of the electrode unit 20 is a second portion P2-1.

For example, in FIGS. 1 and 2, the third portion P3 covering the far half part FH1 of the conductive layer 113-1 relatively far from the light emission unit 10-1 of the electrode unit 20 is a third portion P3-1.

For example, in FIGS. 1 and 4, the first portion P1 covering a region between the light emission unit 10-2 and the electrode unit 20 of the conductive layer 113-1 is a first portion P1-2.

For example, in FIGS. 1 and 4, the second portion P2 covering the near half part NH2 of the conductive layer 113-1 relatively close to the light emission unit 10-2 of the electrode unit 20 is a second portion P2-2.

For example, in FIGS. 1 and 4, the third portion P3 covering the far half part FH2 of the conductive layer 113-1 relatively far from the light emission unit 10-2 of the electrode unit 20 is a third portion P3-2.

In the conductive layer 113-1, a degassing unit 113-1a is provided in the first portion P1 and/or the second portion P2 and the third portion P3 corresponding to each light emission unit 10. As illustrated in FIGS. 1 to 3, the degassing unit 113-1a is, for example, a cutout.

As an example, as illustrated in FIG. 1, four degassing units 113-1a are provided in equal intervals in the circumferential direction of the electrode unit 20.

At least a part of the degassing unit 113-1a is preferably provided in a position within 35 μm, more preferably at a position within 30 μm, still more preferably at a position within 25 μm, and yet still more preferably at a position within 20 μm from the oxidized region 103b′ of the second oxidized constriction layer 103′ in the conductive layer 113-1. Hereinafter, from the symmetry of arrangement of the plurality of light emission units 10, the electrode unit 20, and the plurality of degassing units 113-1a (113-1a-1 to 113-1a-4) in FIG. 1, only description related to the light emission unit 10-1 and the light emission unit 10-2 will be representatively made.

(Description Related to Light Emission Unit 10-1)

For example, in FIG. 1, the degassing unit 113-1a provided in the second portion P2-1 corresponding to the light emission unit 10-1 is the degassing unit 113-1a-1.

For example, in FIG. 1, the degassing unit 113-1a provided in the third portion P3-1 corresponding to the light emission unit 10-1 is the degassing unit 113-1a-3.

For example, in FIG. 1, the degassing unit 113-1a provided across the second portion P2-1 and the third portion P3-1 corresponding to the light emission unit 10-1 is the degassing unit 113-1a-2 and the degassing unit 113-1a-4.

More specifically, as illustrated in FIGS. 1 and 2, the degassing unit 113-1a-1 is provided at least at a part of the second portion P2-1 covering the side surface of the near half part NH1.

The degassing unit 113-1a-3 is provided at least at a part of the third portion P3-1 covering the side surface of the far half part FH1.

As illustrated in FIGS. 1 and 3, the degassing unit 113-1a-2 is provided in least across a part of the second portion P2-1 covering the side surface of the near half part NH1 and a part of the third portion P3-1 covering the side surface of the far half part FH1.

The degassing unit 113-1a-4 is provided in least across a part of the second portion P2-1 covering the side surface of the near half part NH1 and a part of the third portion P3-1 covering the side surface of the far half part FH1.

As illustrated in FIGS. 1 and 2, the degassing unit 113-1a-1 is provided at least at a position corresponding to an outer circumferential surface of the second oxidized constriction layer 103′ (an outer circumferential surface of the oxidized region 103b′) in a part of the second portion P2-1 covering the side surface of the near half part NH1.

The degassing unit 113-1a-3 is provided at least at a position corresponding to an outer circumferential surface of the second oxidized constriction layer 103′ (an outer circumferential surface of the oxidized region 103b′) in a part of the third portion P3-1 covering the side surface of the far half part FH1.

As illustrated in FIGS. 1 and 3, the degassing unit 113-1a-2 is provided in least across a position corresponding to the outer circumferential surface of the second oxidized constriction layer 103′ (the outer circumferential surface of the oxidized region 103b′) in a part of the second portion P2-1 covering the side surface of the near half part NH1 and a position corresponding to the outer circumferential surface of the second oxidized constriction layer 103′ (the outer circumferential surface of the oxidized region 103b′) in a part of the third portion P3-1 covering the side surface of the far half part FH1.

The degassing unit 113-1a-4 is provided in least across a position corresponding to the outer circumferential surface of the second oxidized constriction layer 103′ (the outer circumferential surface of the oxidized region 103b′) in a part of the second portion P2-1 covering the side surface of the near half part NH1 and a position corresponding to the outer circumferential surface of the second oxidized constriction layer 103′ (the outer circumferential surface of the oxidized region 103b′) in a part of the third portion P3-1 covering the side surface of the far half part FH1.

As illustrated in FIGS. 1 and 2, the degassing unit 113-1a-1 is provided at least at a part of the second portion P2-1 covering the upper surface of the near half part NH1. More specifically, the degassing unit 113-1a-1 is provided at least at a part of the second portion P2-1 covering the outer circumferential part of the upper surface of the near half part NH1.

The degassing unit 113-1a-3 is provided at least at a part of the third portion P3-1 covering the upper surface of the far half part FH1. More specifically, the degassing unit 113-1a-3 is provided at least at a part of the third portion P3-1 covering the outer circumferential part of the upper surface of the far half part FH.

As illustrated in FIGS. 1 and 3, the degassing unit 113-1a-2 is provided in least across a part of the second portion P2-1 covering the upper surface of the near half part NH1 (more specifically, the outer circumferential part of the upper surface) and a part of the third portion P3-1 covering the upper surface of the far half part FH1 (more specifically, the outer circumferential part of the upper surface).

The degassing unit 113-1a-4 is provided in least across a part of the second portion P2-1 covering the upper surface of the near half part NH1 and a part of the third portion P3-1 covering the upper surface of the far half part FH1.

As illustrated in FIGS. 1 and 2, the degassing unit 113-1a-1 is provided at least at a part of the second portion P2-1 covering a corner part formed by the upper surface and the side surface of the near half part NH1.

The degassing unit 113-1a-3 is provided at least at a part of the third portion P3-1 covering a corner part formed by the upper surface and the side surface of the far half part FH1.

As illustrated in FIGS. 1 and 3, the degassing unit 113-1a-2 is provided in least across a part of the second portion P2-1 covering a corner part formed by the upper surface and the side surface of the near half part NH1 and a part of the third portion P3-1 covering a corner part formed by the upper surface and the side surface of the far half part FH1.

The degassing unit 113-1a-4 is provided in least across a part of the second portion P2-1 covering a corner part formed by the upper surface and the side surface of the near half part NH1 and a part of the third portion P3-1 covering a corner part formed by the upper surface and the side surface of the far half part FH1.

As illustrated in FIGS. 1 and 2, the degassing unit 113-1a-1 is provided at least at a boundary between the first portion P1-1 and the second portion P2-1.

As illustrated in FIG. 2, the insulating layer 109 is arranged between the second portion P2-1 of the conductive layer 113-1 and the near half part NH1 of the electrode unit 20 and between the third portion P3-1 of the conductive layer 113-1 and the far half part FH1 of the electrode unit 20.

In general, an insulator has a lower gas barrier property than that of metals and semiconductors.

That is, the insulating layer 109 has a lower gas barrier property than that of each semiconductor layer of the conductive layer 113-1 and the electrode unit 20.

The thickness of the insulating layer 109 is preferably equal to or greater than 0.1 μm and equal to or less than 2.0 μm.

(Description Related to Light Emission Unit 10-2)

For example, in FIG. 1, the degassing unit 113-1a provided in the second portion P2-2 corresponding to the light emission unit 10-2 is the degassing unit 113-1a-1 and the degassing unit 113-1a-2.

For example, in FIG. 1, the degassing unit 113-1a provided in the third portion P3-2 corresponding to the light emission unit 10-2 is the degassing unit 113-1a-3 and the degassing unit 113-1a-4.

More specifically, as illustrated in FIGS. 1 to 4, the degassing unit 113-1a-1 is provided at least at a part of the second portion P2-2 covering the side surface of the near half part NH2.

The degassing unit 113-1a-2 is provided at least at a part of the second portion P2-2 covering the side surface of the near half part NH2.

The degassing unit 113-1a-3 is provided at least at a part of the third portion P3-2 covering the side surface of the far half part FH2.

The degassing unit 113-1a-4 is provided at least at a part of the third portion P3-2 covering the side surface of the far half part FH2.

The degassing unit 113-1a-1 is provided at least at a part of the second portion P2-2 covering the upper surface of the near half part NH2. More specifically, the degassing unit 113-1a-1 is provided at least at a part of the second portion P2-2 covering the outer circumferential part of the upper surface of the near half part NH2.

The degassing unit 113-1a-2 is provided at least at a part of the second portion P2-2 covering the upper surface of the near half part NH2. More specifically, the degassing unit 113-1a-2 is provided at least at a part of the second portion P2-2 covering the outer circumferential part of the upper surface of the near half part NH2.

The degassing unit 113-1a-3 is provided at least at a part of the third portion P3-2 covering the upper surface of the far half part FH2. More specifically, the degassing unit 113-1a-3 is provided at least at a part of the third portion P3-2 covering the outer circumferential part of the upper surface of the far half part FH2.

The degassing unit 113-1a-4 is provided at least at a part of the third portion P3-2 covering the upper surface of the far half part FH2. More specifically, the degassing unit 113-1a-4 is provided at least at a part of the third portion P3-2 covering the outer circumferential part of the upper surface of the far half part FH2.

The degassing unit 113-1a-1 is provided at least at a part of the second portion P2-2 covering a corner part formed by the upper surface and the side surface of the near half part NH2.

The degassing unit 113-1a-2 is provided at least at a part of the second portion P2-2 covering a corner part formed by the upper surface and the side surface of the near half part NH2.

The degassing unit 113-1a-3 is provided at least at a part of the third portion P3-2 covering a corner part formed by the upper surface and the side surface of the far half part FH2.

The degassing unit 113-1a-4 is provided at least at a part of the third portion P3-2 covering a corner part formed by the upper surface and the side surface of the far half part FH2.

As illustrated in FIG. 4, the insulating layer 109 is arranged between the second portion P2-2 of the conductive layer 113-1 and the near half part NH2 of the electrode unit 20 and between the third portion P3-2 of the conductive layer 113-1 and the far half part FH2 of the electrode unit 20.

The insulating layer 109 has a lower gas barrier property than that of each semiconductor layer of the conductive layer 113-1 and the electrode unit 20.

The thickness of the insulating layer 109 is preferably equal to or greater than 0.1 μm and equal to or less than 2.0 μm.

### 2. <Operation of Surface Emitting Laser Apparatus According to First Example of Embodiment of the Present Technology>

In the surface emitting laser apparatus 1-1, the current injected from the laser driver to the anode electrode 111 via the electrode unit 20 is supplied to the light emission unit 10 to be emitted via the first contact layer 101. The current supplied to the light emission unit 10 is injected into the active layer 105 via the first multilayer film reflecting mirror 102, the first oxidized constriction layer 103, and the first spacer layer 104 of the light emission unit 10. As a result, when the active layer 105 emits light, the light is amplified while being repeatedly reflected between the first and second multilayer film reflecting mirrors 102, 107, and, when the oscillation conditions are satisfied, the light is emitted as laser light to the back surface side of the substrate 100.

### 3. <Method for Manufacturing Surface Emitting Laser Apparatus According to First Example of Embodiment of the Present Technology>

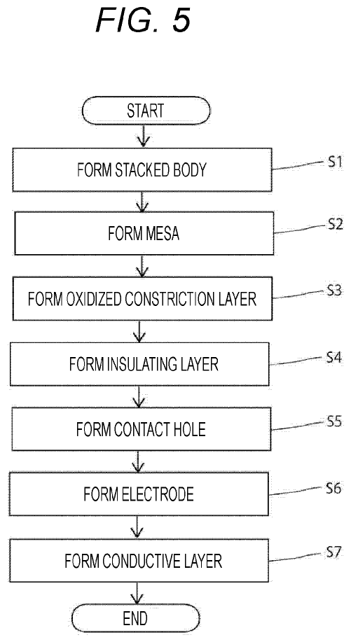

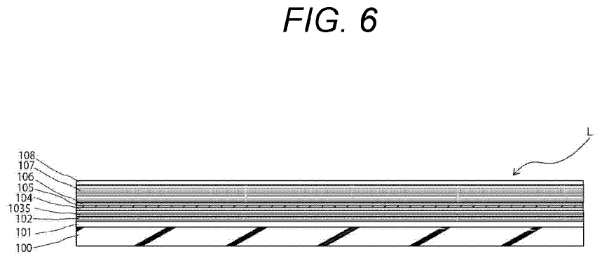

Hereinafter, a method for manufacturing the surface emitting laser apparatus 1-1 according to a first example will be described with reference to the flowchart of FIG. 5 and the cross-sectional views of FIGS. 6 to 13.

Here, as an example, a plurality of surface emitting laser apparatuses 1-1 is simultaneously generated on one wafer which is a base material of the substrate 100 by a semiconductor manufacturing method. Next, the plurality of continuous integrated surface emitting laser apparatuses 1-1 is separated from each other by dicing to obtain a plurality of surface emitting laser apparatuses 1-1 for each apparatus (for each chip).

In the first step S1, a stacked body L is generated. Specifically, as illustrated in FIG. 6, the first contact layer 101, the first multilayer film reflecting mirror 102, the first spacer layer 104, the active layer 105, the second spacer layer 106, the second multilayer film reflecting mirror 107 including a selected oxidized layer 103S therein, and the second contact layer 108 are stacked in this order on the substrate 100 by using a chemical vapor deposition (CVD) method, for example, a metal organic chemical vapor deposition (MOCVD) method to generate the stacked body L.

In the next step S2, a mesa is formed.

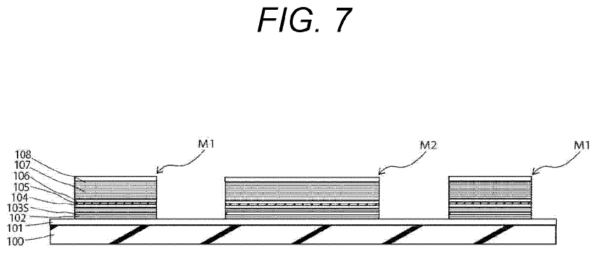

Specifically, as illustrated in FIG. 7, the stacked body L is etched to form mesas M1, M2.

More specifically, first, a resist pattern for forming the mesas M1, M2 to be mesa structures MS1, MS2 is generated on the second contact layer 108 of the stacked body L. Next, the stacked body L is etched (for example, wet etching using a sulfuric acid-based etchant) using the resist pattern as a mask to form the mesas M1, M2. Here, etching is performed until the first contact layer 101 is exposed. Thereafter, the resist pattern is removed.

In the next step S3, an oxidized constriction layer is formed.

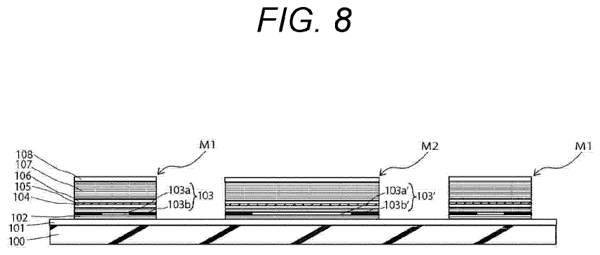

Specifically, as illustrated in FIG. 8, the peripheral portions of the selected oxidized layer 103S of the mesas M1, M2 are oxidized to generate the first and second oxidized constriction layers 103, 103′.

Specifically, the mesas M1, M2 are exposed to a water vapor atmosphere, and the selected oxidized layer 103S is oxidized (selectively oxidized) from the side surface to form the first and second oxidized constriction layers 103, 103′ in which the non-oxidized region is surrounded by the oxidized region.

At this time, gas is intermittently or continuously generated from the oxidized region of each oxidized constriction layer by heat during selective oxidation.

In the next step S4, the insulating layer 109 is formed.

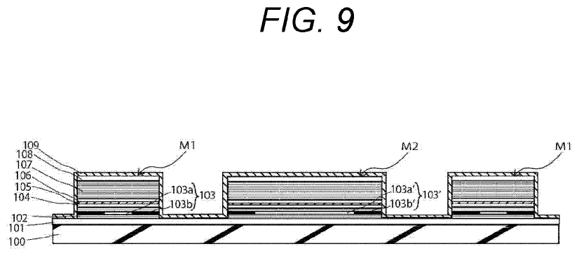

Specifically, as illustrated in FIG. 9, the insulating layer 109 is formed on the stacked body in which the mesas M1, M2 are formed.

In the next step S5, the contact hole is formed.

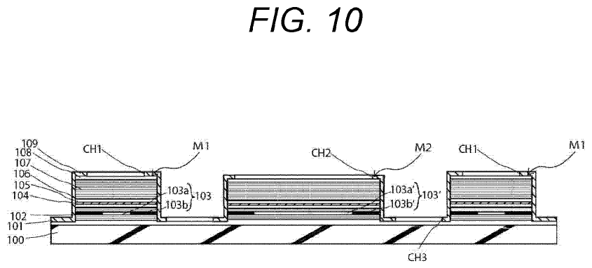

Specifically, a resist pattern for forming the cathode electrode 110, the electrode 112, and the anode electrode 111 is generated on the stacked body in which the mesas M1, M2 are formed and the insulating layer 109 is formed. Next, using this resist pattern as a mask, the insulating layer 109 at a portion where the cathode electrode 110, the electrode 112, and the anode electrode 111 are to be provided is removed by etching (for example, etching using a hydrofluoric acid-based etchant) to form contact holes CH1, CH2, CH3 (see FIG. 10).

In the next step S6, an electrode is formed.

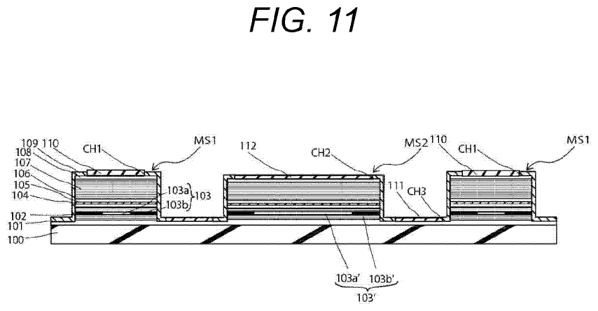

Specifically, for example, an Au/Ti film is formed on the stacked body in which the contact holes CH1, CH2, CH3 are formed by an EB vapor deposition method, and the cathode electrode 110, the electrode 112, and the anode electrode 111 are formed by lifting off the resist and, for example, Au/Ti on the resist (see FIG. 11).

In the final step S7, a conductive layer is formed.

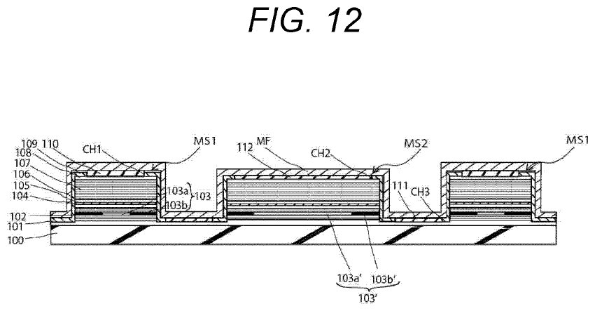

Specifically, first, a metal film MF (for example, gold plating) is formed using, for example, a plating method (see FIG. 12). Note that, before the plating method is used, an underlayer (for example, nickel plating, chromium plating, and the like) to be a plating base is formed at a portion of the insulating layer 109 where the conductive layer 113-1 is to be formed, for example, by vapor deposition, sputtering, or the like. The thickness of the metal film MF is a thickness (for example, about 2 μm) that can sufficiently prevent a voltage drop.

Next, a resist pattern for removing a portion covering each electrode and a portion where the degassing unit 113-1a is to be formed is formed on the metal film MF.

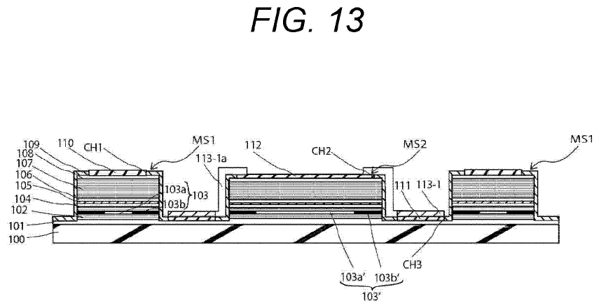

Finally, the metal film MF is etched (for example, wet etching using a sulfuric acid-based etchant) using the resist pattern as a mask to form the conductive layer 113-1 having the degassing unit 113-1a (see FIG. 13). Note that the conductive layer 113-1 may be formed by lift-off instead of etching.

Thereafter, processing such as annealing, thinning by polishing the back surface of the wafer, and non-reflection coating on the back surface of the wafer is performed, and a plurality of surface emitting laser apparatuses 1-1 is formed on one wafer. Thereafter, the plurality of surface emitting laser apparatuses 1-1 is separated for each apparatus (for each chip) by dicing.

### 4. <Action of Surface Emitting Laser Apparatus According to First Example of Embodiment of the Present Technology>

In the surface emitting laser apparatus 1-1, part of the gas generated in the second oxidized constriction layer 103′ of the electrode unit 20 penetrates (passes) the insulating layer 109 in the thickness direction thereof and is released to the outside from the degassing unit 113-1 a, and the other part moves in the insulating layer 109 along the in-plane direction of the insulating layer 109 and is released to the outside from the degassing unit 113-1 a.

### 5. <Effects of Surface Emitting Laser Apparatus According to First Example of Embodiment of the Present Technology and Effects of Method for Manufacturing the Surface Emitting Laser Apparatus>

The surface emitting laser apparatus according to an embodiment of the present technology and effects of method for manufacturing the surface emitting laser apparatus will be described below.

The surface emitting laser apparatus 1-1 according to the first example includes the stacked structure LS having a plurality of light emission units 10 including the first oxidized constriction layer 103 and the electrode unit 20 including the second oxidized constriction layer 103′ at different positions in an in-plane direction, and the conductive layer 113-1 that makes each of the light emission units 20 and the electrode unit 20 conductive. The conductive layer 113-1 has a first portion P1 that covers a region between each light emission unit 10 and the electrode unit 20 of the stacked structure LS, a second portion P2 that covers a near half part NH relatively close to the light emission unit 10 of the electrode unit 20, and a third portion that covers a far half part relatively far from the light emission unit 10 of the electrode unit 20. The degassing unit 113-1a is provided in the first portion P1 and/or the second portion P2 and the third portion P3.

In this case, the gas generated in the oxidized region of the second oxidized constriction layer 103′ is discharged to the outside through the degassing unit 113-1a provided in the first portion P1 and/or the second portion P2 and the third portion P3.

As a result, defects such as gas swelling of the conductive layer 113-1 can be suppressed. Moreover, defects such as gas swelling of the electrode 112 provided in the top of the electrode unit 20 can also be suppressed.

As a result, according to the surface emitting laser apparatus 1-1, it is possible to provide the surface emitting laser apparatus capable of improving the yield.

Note that, in the surface emitting laser apparatus 1-1, there is a possibility that gas is generated in the second oxidized constriction layer 103′ due to, for example, heat generated at the time of operation, an environmental temperature, and the like even after manufacturing. Therefore, by providing the degassing unit 113-1a, the reliability of the surface emitting laser apparatus 1-1 after a product is finished can be improved.

On the other hand, in a case where the degassing unit is not provided in the first portion P1 and/or the second portion P2 (former) and/or the third portion P3 (latter) of the conductive layer, gas cannot be discharged to the outside from the portion where the degassing unit is not provided (former and/or latter), and a defect such as gas swelling occurs in the portion and the electrode provided on the top of the electrode unit. Therefore, the yield cannot be improved, and the reliability as a product is also poor.

The degassing unit 113-1a is a cutout. Therefore, the degassing unit 113-1a can be easily formed in the conductive layer 113-1. Specifically, the degassing unit 113-1a can be formed during patterning of the conductive layer 113-1.

The surface emitting laser apparatus 1-1 according to the first example further includes the insulating layer 109 arranged between the first portion P1 and the stacked structure LS, between the second portion P2 and the near half part NH, and between the third portion P3 and the far half part FH.

As a result, the gas generated in the oxidized region of the second oxidized constriction layer 103′ can be quickly guided (passed) to the degassing unit 113-1a through the insulating layer 109 having a low gas barrier property, and the degassing efficiency can be enhanced.

Here, as the thickness of the insulating layer 109 increases, the passability of the gas, which is generated in the oxidized region of the second oxidized constriction layer 103′, moves along the in-plane direction in the insulating layer 109, and reaches the degassing unit 113-1a, in the insulating layer 109 is improved. On the other hand, as the thickness of the insulating layer 109 decreases, the penetration of the gas, which is generated in the second oxidized constriction layer 103′, passes through (penetrates) the thickness direction in the insulating layer 109, and reaches the degassing unit 113-1a, in the insulating layer 109 is improved.

However, when the thickness of the insulating layer 109 is too thin, the insulating layer 109 cannot be stably formed on the side surface of the electrode unit 20 (the side surface of the mesa structure MS2), and the insulation between the conductive layer 113-1 and each semiconductor layer of the electrode unit 20 is deteriorated.

Therefore, in the surface emitting laser apparatus 1-1 according to the first example, the thickness of the insulating layer 109 is set to equal to or greater than 0.1 μm and equal to or less than 2.0 μm.

The degassing unit 113-1a is provided at least in a part of the second portion P2 covering the side surface of the near half part NH and a part of the third portion P3 covering the side surface of the far half part FH. As a result, at least a part of the gas generated in the second oxidized constriction layer 103′ can be sent to the degassing unit 113-1a through a relatively short path.

The degassing unit 113-1a is provided in a position corresponding to the outer circumferential surface of the second oxidized constriction layer 103′ in a part of the second portion P2 covering the side surface of the near half part NH and a part of the third portion P3 covering the side surface of the far half part FH. As a result, at least a part of the gas generated in the second oxidized constriction layer 103′ can be sent to the degassing unit 113-1a through the shortest path.

The degassing unit 113-1a is provided at least in a part of the second portion P2 covering the upper surface of the near half part NH and a part of the third portion covering the upper surface of the far half part FH. As a result, at least a part of the gas generated in the second oxidized constriction layer 103′ can be sent to the degassing unit 113-1a through a relatively short path.

The degassing unit 113-1a is provided at least in a part of the second portion P2 covering the outer circumferential part of the upper surface of the near half part NH and a part of the third portion P3 covering the outer circumferential part of the upper surface of the far half part FH. As a result, at least a part of the gas generated in the second oxidized constriction layer 103′ can be sent to the degassing unit 113-1a through a shorter path.

The degassing unit 113-1a is provided at least in a part of the second portion P2 covering a corner part formed by the upper surface and the side surface of the near half part NH and a part of the third portion P3 covering a corner part formed by the upper surface and the side surface of the far half part FH. As a result, at least a part of the gas generated in the second oxidized constriction layer 103′ can be sent to the degassing unit 113-1a through a relatively short path.

The degassing unit 113-1a is provided at least at a boundary between the first portion P1 and the second portion P2.

At least a part of the gas generated in the second oxidized constriction layer 103′ can be sent to the degassing unit 113-1a through a relatively short path.

At least a part of the degassing unit 113-1a is preferably provided at a position within 35 μm from an oxidized region of the second oxidized constriction layer 103′ in the conductive layer 113-1. As a result, the distance from the second oxidized constriction layer 103′ as a gas generation source to the degassing unit 113-1a can be set to a distance at which the gas can be quickly and reliably discharged.

The conductive layer 113-1 makes each of the plurality of light emission units 10 and the electrode unit 20 conductive with each other. As a result, the number of electrode units 20 can be reduced, and the configuration can be simplified.

The conductive layer 113-1 covers a region between each of the plurality of light emission units 10 and the electrode unit 20 and the outer circumferential surface and the outer circumferential part of the upper surface of the electrode unit 20 in the stacked structure LS. As a result, a current can be efficiently supplied from the electrode unit 20 to each light emission unit 10.

A central interval between two adjacent light emission units 10 among the plurality of light emission units 10 is preferably equal to or less than 35 μm. In this case, since the current density of the electrode unit 20 common to the plurality of light emission units 10 increases and the temperature tends to be high, the gas pressure of the gas generated in the second oxidized constriction layer 103′ tends to increase. Therefore, it is particularly effective to provide the degassing unit 113-1a in the conductive layer 113-1. In addition, even in a case where high output is required, the current density of the electrode unit 20 increases, and the gas pressure tends to increase. Therefore, it is particularly effective to provide the degassing unit 113-1a in the conductive layer 113-1.

The light emission unit 20 includes the first multilayer film reflecting mirror 102 including the first oxidized constriction layer 103 therein, the second multilayer film reflecting mirror 107, and an active layer 105 arranged between the first and second multilayer film reflecting mirrors 102, 107, and the electrode unit 20 may include the first multilayer film reflecting mirror 102 including the second oxidized constriction layer 103′ therein, the second multilayer film reflecting mirror 107, and the active layer 105 arranged between the first and second multilayer film reflecting mirrors 102, 107. Therefore, the light emission unit 10 and the electrode unit 20 can be formed in parallel by the semiconductor manufacturing process.

The light emission unit 20 may include the substrate 100 arranged on a side opposite to the active layer 105 side with respect to the first multilayer film reflecting mirror 102 and transparent to an oscillation wavelength of the light emission unit 20, and the light emission unit 20 may emit light to a back surface side of the substrate 100. As a result, the surface emitting laser apparatus 1-1 having a thin thickness and low power consumption can be achieved.

The method for manufacturing the surface emitting laser apparatus 1-1 includes: a step of forming the stacked body L by stacking the first multilayer film reflecting mirror 102 including the selected oxidized layer 103S therein, the active layer 105, and the second multilayer film reflecting mirror 107 in this order on the substrate 100; a step of etching the stacked body L to form the first mesa M1 including one part of the selected oxidized layer 103S and the second mesa M2 including another part of the selected oxidized layer 103S; a step of oxidizing the one part and the another part of the selected oxidized layer 103S from side surfaces to form the stacked structure LS having the light emission unit 10 including the first oxidized constriction layer 103 and the electrode unit 20 including the second oxidized constriction layer 103′; and a step of forming the conductive layer 113-1 including the first portion P1 covering the region between the light emission unit 10 and the electrode unit 20 of the stacked structure LS, the second portion P2 covering the near half part NH of the electrode unit 20, the second portion P2 being relatively close to the light emission unit 10, and the third portion P3 covering the far half part FH of the electrode unit 20, the far half part FH being relatively far from the light emission unit 10. In the conductive layer 113-1, a degassing unit 113-1a is formed in the first portion P1 and/or the second portion P2 and the third portion P3.

In this case, the gas generated in the oxidized region of the second oxidized constriction layer 103′ is discharged to the outside through the degassing unit 113-1a provided in the first portion P1 and/or the second portion P2 and the third portion P3.

As a result, defects such as gas swelling of the conductive layer 113-1 can be suppressed. Moreover, defects such as gas swelling of the electrode 112 provided in the top of the electrode unit 20 can also be suppressed.

As a result, according to the method for the surface emitting laser apparatus 1-1, it is possible to manufacture the surface emitting laser apparatus 1-1 capable of improving the yield.

The degassing unit 113-1a is a cutout. Therefore, the degassing unit 113-1a can be easily formed in the conductive layer 113-1. The degassing unit 113-1a can be formed during patterning of the conductive layer 113-1.

The method for manufacturing the surface emitting laser apparatus 1-1 according to the first example further includes, after the step of forming the stacked structure LS and before the step of forming the conductive layer 113-1, a step of forming an insulating layer 109 in a region between the light emission unit 10 of the stacked structure LS and the electrode unit 20 and the near half part NH and the far half part FH. As a result, the surface emitting laser apparatus 1-1 having high degassing efficiency can be manufactured.

### 6. <Surface Emitting Laser Apparatuses According to Second to Tenth Examples of Embodiment of the Present Technology>

The surface emitting laser apparatuses 1-2 to 1-10 according to second to tenth examples of an embodiment of the present technology will be described below.

The surface emitting laser apparatuses 1-2 to 1-10 according to the second to tenth examples are different from the surface emitting laser apparatus 1-1 according to the first example in the position where the degassing unit is provided in the conductive layer. The surface emitting laser apparatuses 1-2 to 1-10 according to the second to tenth examples can be manufactured by a manufacturing method similar to the manufacturing method of the surface emitting laser apparatus 1-1 according to the first example.

Regarding the surface emitting laser apparatuses 1-2 to 1-10 according to the second to tenth examples, a common description related to each light emission unit 10 will be given.

(Surface Emitting Laser Apparatus According to Second Example)

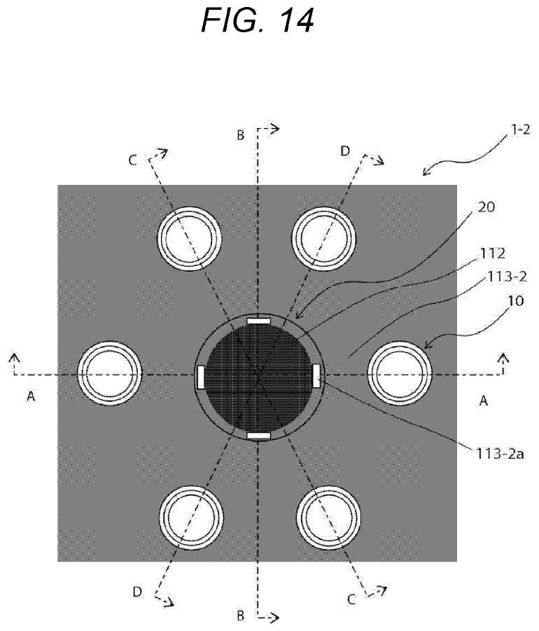

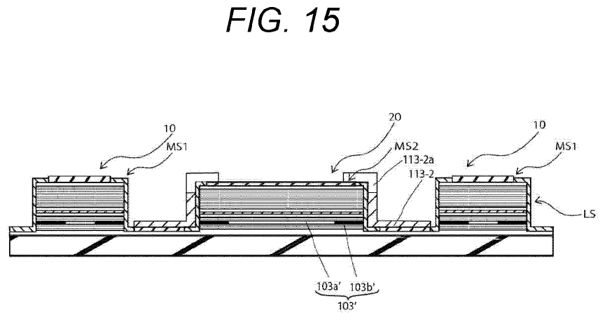

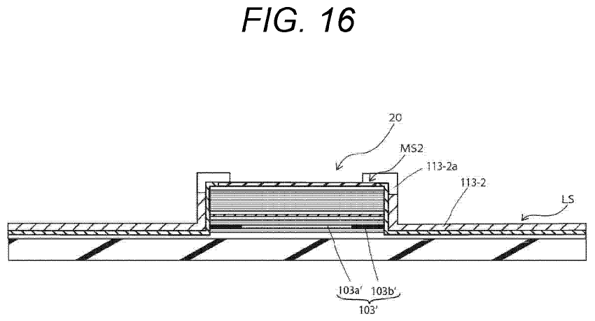

Hereinafter, a surface emitting laser apparatus 1-2 according to the second example will be described with reference to FIGS. 14 to 16. FIG. 14 is a plan view of the surface emitting laser apparatus 1-2. FIG. 15 is a cross-sectional view taken along line A-A of FIG. 14. FIG. 16 is a cross-sectional view taken along line B-B of FIG. 14. The cross section taken along line C-C and the cross section taken along line D-D in FIG. 14 is similar to the cross section taken along line C-C in FIG. 1.

As illustrated in FIGS. 14 to 16, in the surface emitting laser apparatus 1-2, the degassing unit 113-2a is provided at least in a part covering the outer circumferential part of the upper surface of the near half part NH of the second portion P2 covering the near half part NH of the electrode unit 20 of the conductive layer 113-2 and a part covering the outer circumferential part of the upper surface of the far half part FH of the third portion P3 covering the far half part FH of the electrode unit 20 of the conductive layer 113-2.

More specifically, each degassing unit 113-2a is a notch part provided in a part covering the corner part formed by the upper surface and the side surface of the near half part NH of the second portion P2 covering the near half part NH of the electrode unit 20 of the conductive layer 113-2 and a part covering the corner part formed by the upper surface and the side surface of the far half part FH of the third portion P3 covering the far half part FH of the electrode unit 20 of the conductive layer 113-2.

(Surface Emitting Laser Apparatus According to Third Example)

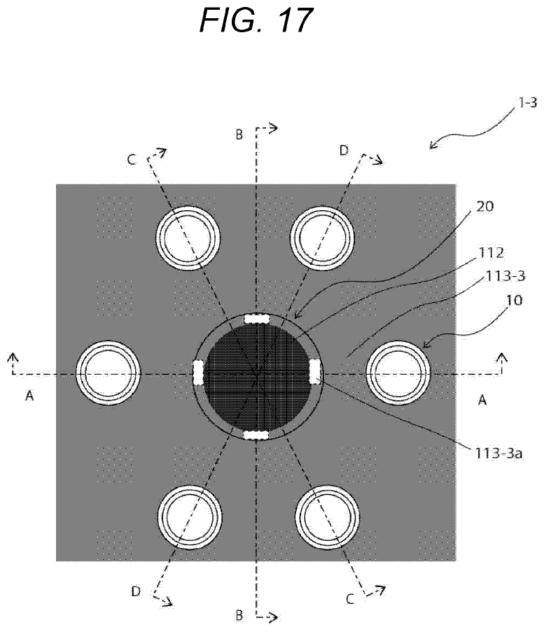

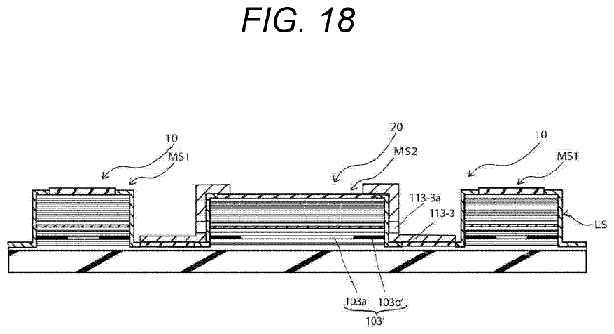

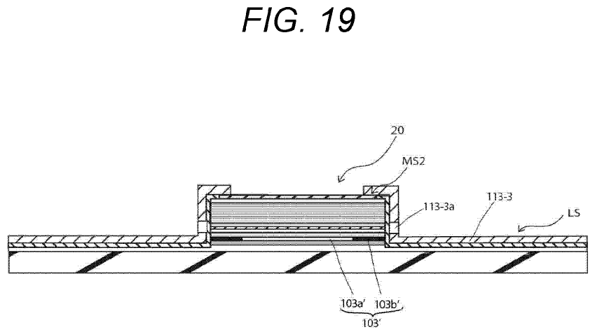

Hereinafter, a surface emitting laser apparatus 1-3 according to the third example will be described with reference to FIGS. 17 to 19. FIG. 17 is a plan view of the surface emitting laser apparatus 1-3. FIG. 18 is a cross-sectional view taken along line A-A of FIG. 17. FIG. 19 is a cross-sectional view taken along line B-B of FIG. 17. The cross section taken along line C-C and the cross section taken along line D-D in FIG. 17 is similar to the cross section taken along line C-C in FIG. 1.

As illustrated in FIGS. 17 to 19, in the surface emitting laser apparatus 1-3, each degassing unit 113-3a is an opening provided in a part covering the side surface of the near half part NH of the second portion P2 covering the near half part NH of the electrode unit 20 of the conductive layer 113-3 and a part covering the side surface of the far half part FH of the third portion P3 covering the far half part FH of the electrode unit 20 of the conductive layer 113-3.

(Surface Emitting Laser Apparatus According to Fourth Example)

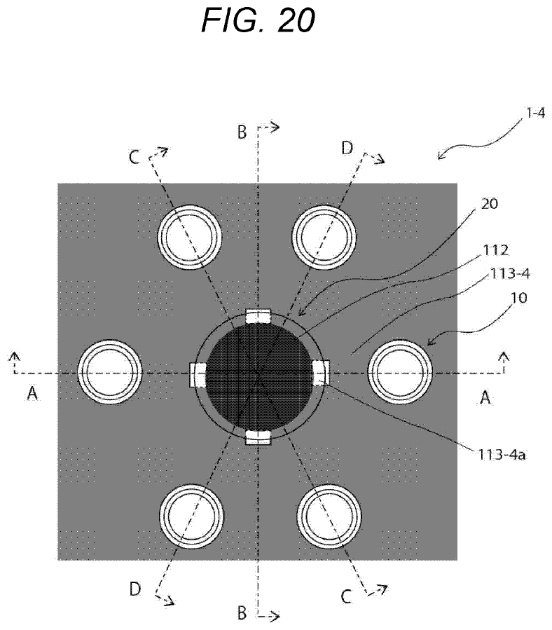

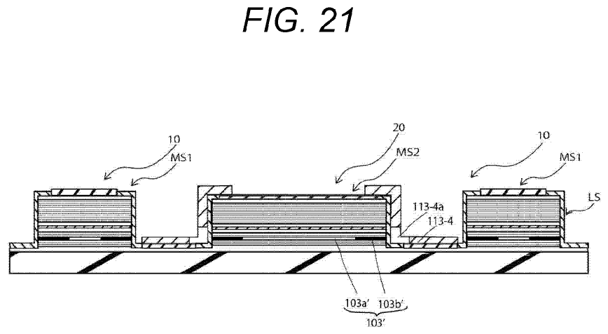

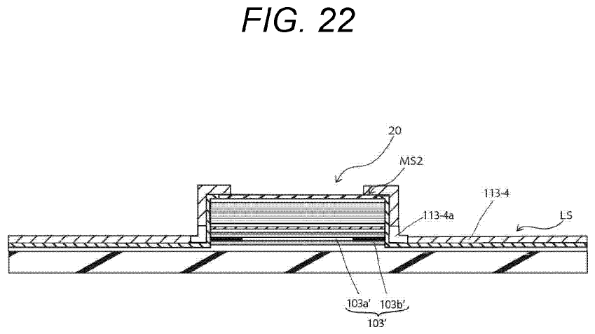

Hereinafter, a surface emitting laser apparatus 1-4 according to the fourth example will be described with reference to FIGS. 20 to 22. FIG. 20 is a plan view of the surface emitting laser apparatus 1-4. FIG. 21 is a cross-sectional view taken along line A-A of FIG. 20. FIG. 22 is a cross-sectional view taken along line B-B of FIG. 20. The cross section taken along line C-C and the cross section taken along line D-D in FIG. 20 is similar to the cross section taken along line C-C in FIG. 1.

As illustrated in FIGS. 20 to 22, in the surface emitting laser apparatus 1-4, each degassing unit 113-4a is an opening provided at a boundary (near the bottom portion of the mesa structure MS2) between the first portion P1 covering the region between the light emission unit 10 and the electrode unit 20 in the stacked structure LS and the second portion P2 covering the near half part NH in the conductive layer 113-4.

Each degassing unit 113-4a is provided at least in a position corresponding to the outer circumferential surface of the second oxidized constriction layer 103′ in a part covering the side surface of the near half part NH of the second portion P2 covering the near half part NH of the electrode unit 20 of the conductive layer 113-4 and a position corresponding to the outer circumferential surface of the second oxidized constriction layer 103′ in a part covering the side surface of the far half part FH of the third portion P3 covering the far half part FH of the electrode unit 20 of the conductive layer 113-4.

(Surface Emitting Laser Apparatus According to Fifth Example)

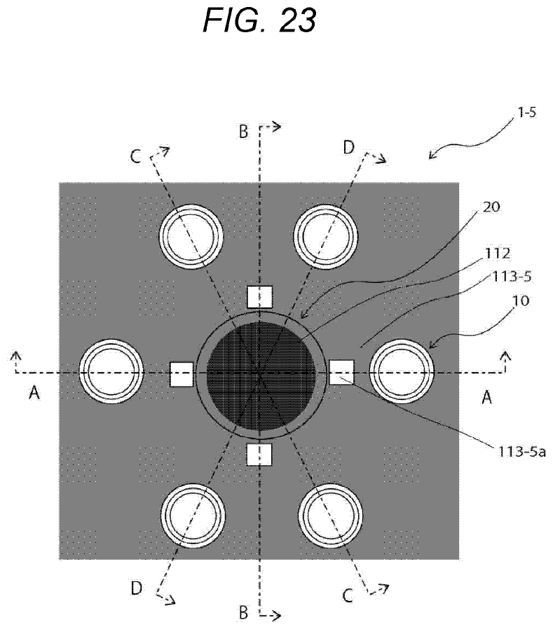

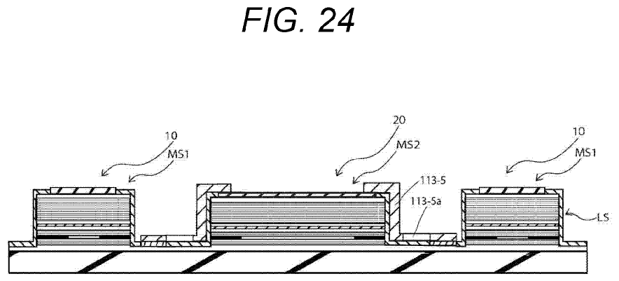

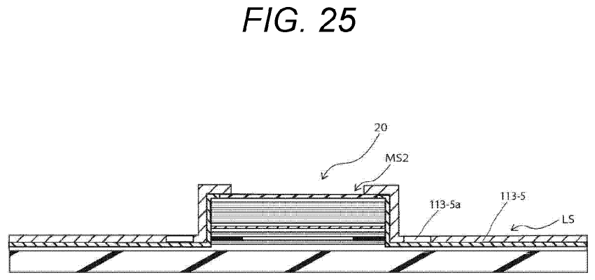

Hereinafter, a surface emitting laser apparatus 1-5 according to the fifth example will be described with reference to FIGS. 23 to 25. FIG. 23 is a plan view of the surface emitting laser apparatus 1-5. FIG. 24 is a cross-sectional view taken along line A-A of FIG. 23. FIG. 25 is a cross-sectional view taken along line B-B of FIG. 23. The cross section taken along line C-C and the cross section taken along line D-D in FIG. 23 is similar to the cross section taken along line C-C in FIG. 1.

As illustrated in FIGS. 23 to 25, in the surface emitting laser apparatus 1-5, each degassing unit 113-5a is an opening provided in the first portion P1 covering the region between the light emission unit 10 and the electrode unit 20 in the stacked structure LS in the conductive layer 113-5.

(Surface Emitting Laser Apparatus According to Sixth Example)

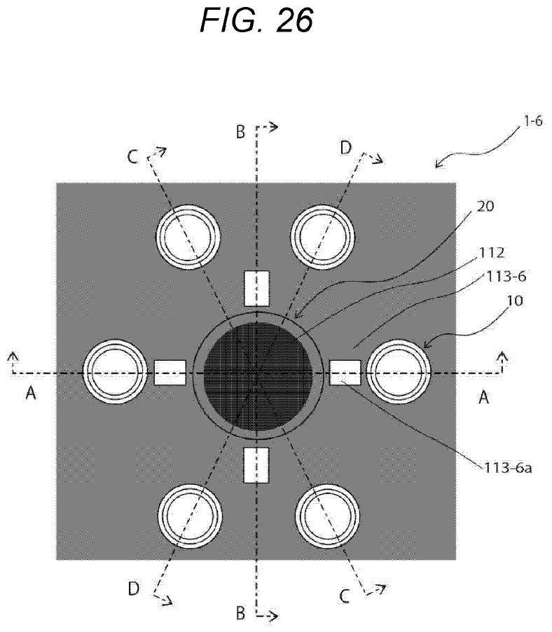

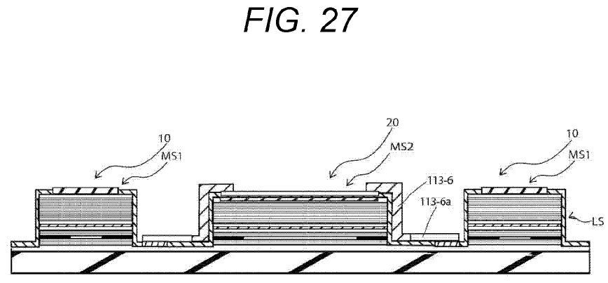

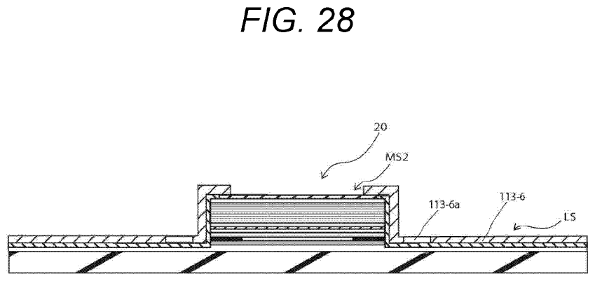

Hereinafter, a surface emitting laser apparatus 1-6 according to the sixth example will be described with reference to FIGS. 26 to 28. FIG. 26 is a plan view of the surface emitting laser apparatus 1-6. FIG. 27 is a cross-sectional view taken along line A-A of FIG. 26. FIG. 28 is a cross-sectional view taken along line B-B of FIG. 26. The cross section taken along line C-C and the cross section taken along line D-D in FIG. 26 is similar to the cross section taken along line C-C in FIG. 1.

As illustrated in FIGS. 26 to 28, in the surface emitting laser apparatus 1-6, each degassing unit 113-6a is a notch or an opening provided in the first portion P1 covering the region between the light emission unit 10 and the electrode unit 20 in the stacked structure LS in the conductive layer 113-6.

(Surface Emitting Laser Apparatus According to Seventh Example)

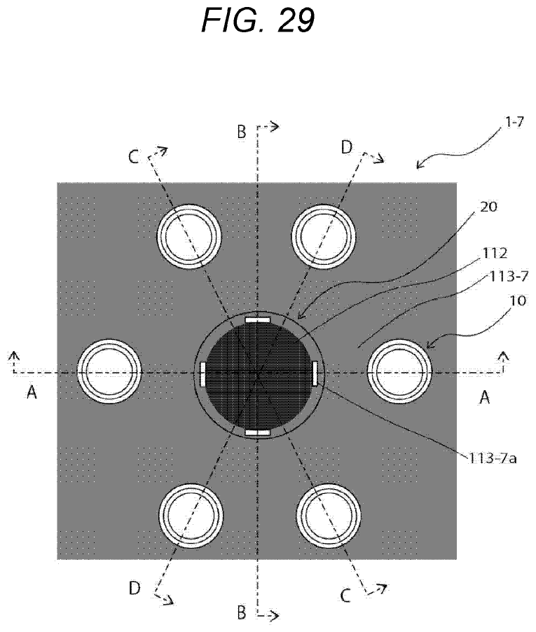

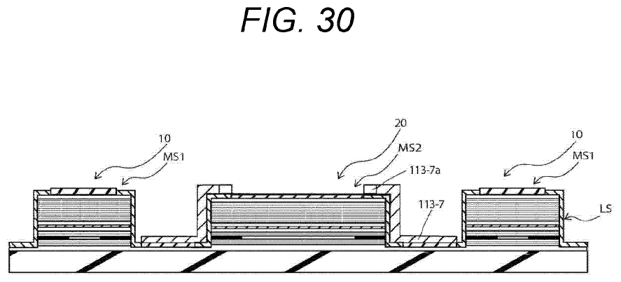

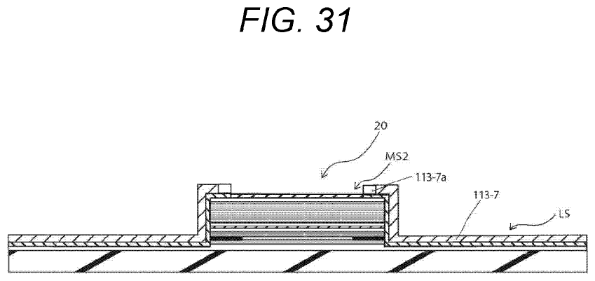

Hereinafter, a surface emitting laser apparatus 1-7 according to the seventh example will be described with reference to FIGS. 29 to 31. FIG. 29 is a plan view of the surface emitting laser apparatus 1-7. FIG. 30 is a cross-sectional view taken along line A-A of FIG. 29. FIG. 31 is a cross-sectional view taken along line B-B of FIG. 29. The cross section taken along line C-C and the cross section taken along line D-D in FIG. 29 is similar to the cross section taken along line C-C in FIG. 1.

As illustrated in FIGS. 29 to 31, in the surface emitting laser apparatus 1-7, each degassing unit 113-7a is a notch provided in a part covering the outer circumferential part of the upper surface of the near half part NH of the second portion P2 covering the near half part NH of the electrode unit 20 of the conductive layer 113-7 and a part covering the outer circumferential part of the upper surface of the far half part FH of the third portion P3 covering the far half part FH of the electrode unit 20 of the conductive layer 113-7.

(Surface Emitting Laser Apparatus According to Eighth Example)

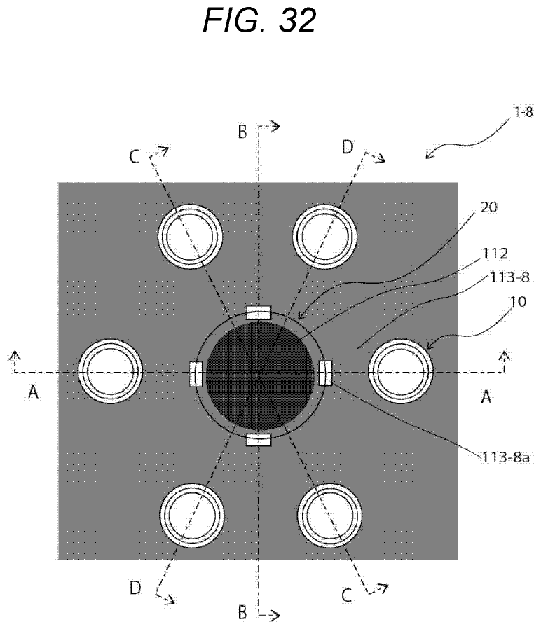

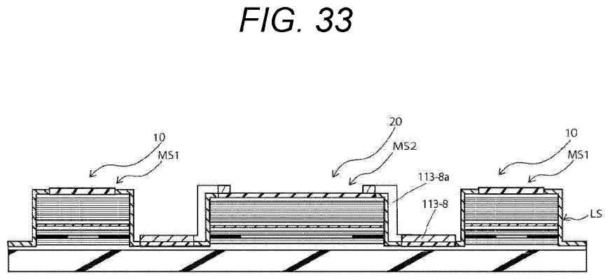

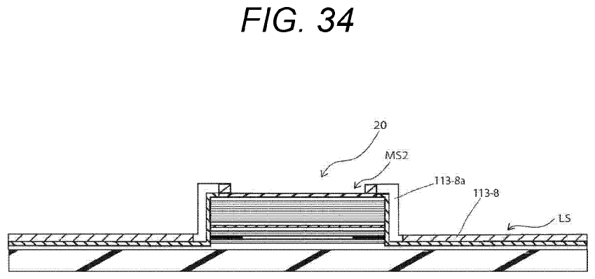

Hereinafter, a surface emitting laser apparatus 1-8 according to the eighth example will be described with reference to FIGS. 32 to 34. FIG. 32 is a plan view of the surface emitting laser apparatus 1-8. FIG. 33 is a cross-sectional view taken along line A-A of FIG. 32. FIG. 34 is a cross-sectional view taken along line B-B of FIG. 32. The cross section taken along line C-C and the cross section taken along line D-D in FIG. 32 is similar to the cross section taken along line C-C in FIG. 1.

As illustrated in FIGS. 32 to 34, in the surface emitting laser apparatus 1-8, each degassing unit 113-8a is provided at least in a part covering the outer circumferential part of the upper surface of the near half part NH of the second portion P2 covering the near half part NH of the electrode unit 20 of the conductive layer 113-8 and a part covering the outer circumferential part of the upper surface of the far half part FH of the third portion P3 covering the far half part FH of the electrode unit 20 of the conductive layer 113-8.

Each degassing unit 113-8a is provided at least in a part covering the corner part formed by the upper surface and the side surface of the near half part NH of the second portion P2 covering the near half part NH of the electrode unit 20 of the conductive layer 113-8 and a part covering the corner part formed by the upper surface and the side surface of the far half part FH of the third portion P3 covering the far half part FH of the electrode unit 20 of the conductive layer 113-8.

Each degassing unit 113-8a is provided at least in a part covering the side surface of the near half part NH of the second portion P2 covering the near half part NH of the electrode unit 20 of the conductive layer 113-8 and a part covering the side surface of the far half part FH of the third portion P3 covering the far half part FH of the electrode unit 20 of the conductive layer 113-8.

Each degassing unit 113-8a is provided at least at a boundary (near the bottom portion of the mesa structure MS2) between the first portion P1 covering the region between the light emission unit 10 and the electrode unit 20 in the stacked structure LS and the second portion P2 in the conductive layer 113-8.

Each degassing unit 113-8a is provided at least in a position corresponding to the outer circumferential surface of the second oxidized constriction layer 103′ in a portion covering the side surface of the near half part NH of the second portion P2 covering the near half part NH of the electrode unit 20 of the conductive layer 113-8 and a position corresponding to the outer circumferential surface of the second oxidized constriction layer 103′ in a portion covering the side surface of the far half part FH of the third portion P3 covering the far half part FH of the electrode unit 20 of the conductive layer 113-4.

Each degassing unit 113-8a is an opening.

(Surface Emitting Laser Apparatus According to Ninth Example)

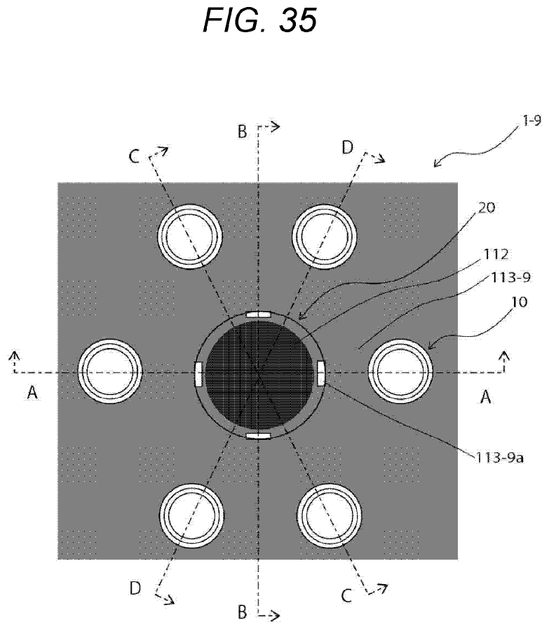

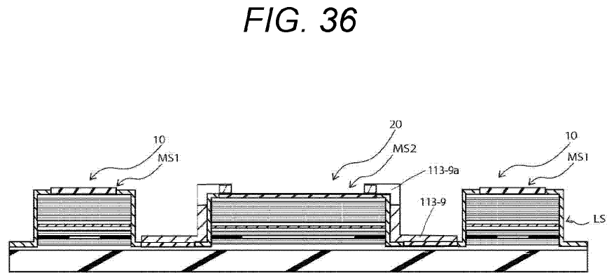

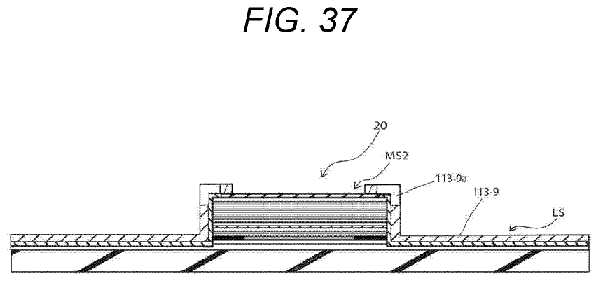

Hereinafter, a surface emitting laser apparatus 1-9 according to the ninth example will be described with reference to FIGS. 35 to 37. FIG. 35 is a plan view of the surface emitting laser apparatus 1-9. FIG. 36 is a cross-sectional view taken along line A-A of FIG. 35. FIG. 37 is a cross-sectional view taken along line B-B of FIG. 35. The cross section taken along line C-C and the cross section taken along line D-D in FIG. 35 is similar to the cross section taken along line C-C in FIG. 1.

As illustrated in FIGS. 35 to 37, in the surface emitting laser apparatus 1-9, each degassing unit 113-9a is an opening provided in a portion covering the corner part formed by the upper surface and the side surface of the near half part NH of the second portion P2 covering the near half part NH of the electrode unit 20 of the conductive layer 113-9 and a portion covering the corner part formed by the upper surface and the side surface of the far half part FH of the third portion P3 covering the far half part FH of the electrode unit 20 of the conductive layer 113-9.

(Surface Emitting Laser Apparatus According to Tenth Example)

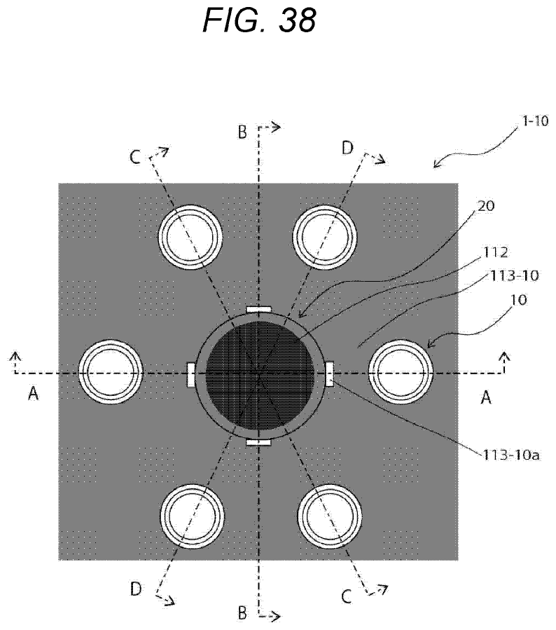

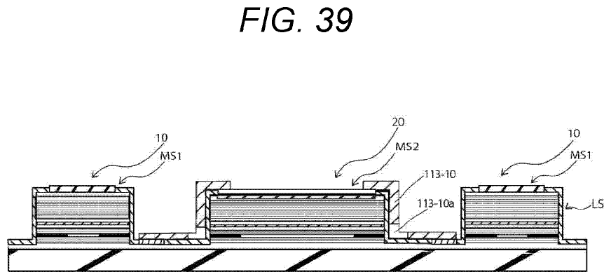

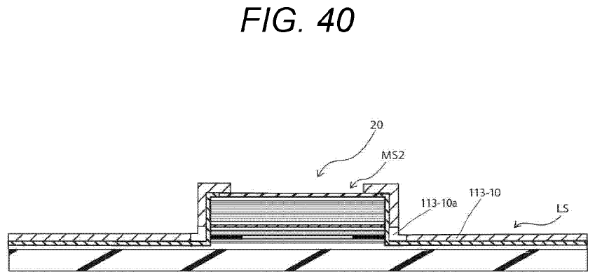

Hereinafter, a surface emitting laser apparatus 1-10 according to the tenth example will be described with reference to FIGS. 38 to 40. FIG. 38 is a plan view of the surface emitting laser apparatus 1-10. FIG. 39 is a cross-sectional view taken along line A-A of FIG. 38. FIG. 40 is a cross-sectional view taken along line B-B of FIG. 38. The cross section taken along line C-C and the cross section taken along line D-D in FIG. 38 is similar to the cross section taken along line C-C in FIG. 1.

As illustrated in FIGS. 38 to 40, in the surface emitting laser apparatus 1-10, each degassing unit 113-10a is an opening provided at a boundary (near the bottom portion of the mesa structure MS2) between the first portion P1 covering the region between the light emission unit 10 and the electrode unit 20 in the stacked structure LS and the second portion P2 in the conductive layer 113-10.

Each degassing unit 113-10a is provided at least in a position corresponding to the outer circumferential surface of the second oxidized constriction layer 103′ in a portion covering the side surface of the near half part NH of the second portion P2 covering the near half part NH of the electrode unit 20 of the conductive layer 113-10 and a position corresponding to the outer circumferential surface of the second oxidized constriction layer 103′ in a portion covering the side surface of the far half part FH of the third portion P3 covering the far half part FH of the electrode unit 20 of the conductive layer 113-10.

### 7. <Surface Emitting Laser Apparatuses According to First to Tenth Modifications of Embodiment of the Present Technology>

The surface emitting laser apparatuses 1-11 to 1-120 according to first to tenth modifications of an embodiment of the present technology will be described below.

The surface emitting laser apparatuses 1-11 to 1-20 according to the first to tenth modifications are different from the surface emitting laser apparatus according to each of the examples described above in that the degassing unit is a thin film. The surface emitting laser apparatuses 1-2 to 1-10 according to the second to tenth examples can be manufactured by a manufacturing method similar to the manufacturing method of the surface emitting laser apparatus 1-1 according to the first example.

In each modification, when the conductive layer is formed, a base layer (for example, nickel plating, chromium plating, and the like) is formed by lift-off using a resist pattern, and then a metal film (for example, metal plating) is formed on a region other than a portion where a thin film as the degassing unit is to be formed using the resist pattern.

In each modification, in the conductive layer, the thin film composed only of the base layer has a significantly lower gas barrier property than the portion where the plating layer is stacked on the base layer.

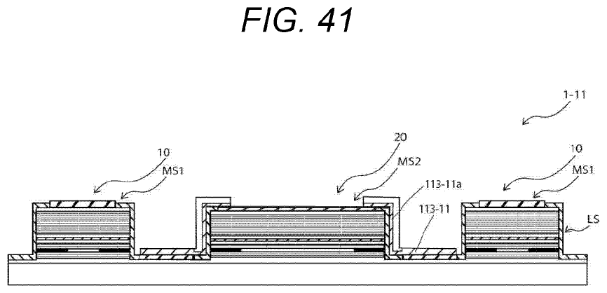

The surface emitting laser apparatus according to each modification has substantially a similar configuration to that of FIG. 1 in plan view. FIGS. 41 to 50 are cross-sectional views (corresponding to cross-sectional views taken along line A-A in FIG. 1) of a surface emitting laser apparatus according to each modification. Other cross sections of the surface emitting laser apparatus according to each modification are substantially similar to the B-B line cross section, the C-C line cross section, and the D-D line cross section in FIG. 1.

(Surface Emitting Laser Apparatus According to First Modification)

In the surface emitting laser apparatus 1-11 according to the first modification, as illustrated in FIG. 41, the position of the degassing unit 113-11a provided in the conductive layer 113-11 corresponds to the position of the degassing unit 113-1a in the surface emitting laser apparatus 1-1 according to the first example illustrated in FIGS. 1 to 4.

The degassing unit 113-11a is a thin film composed only of a base layer of the conductive layer 113-11.

(Surface Emitting Laser Apparatus According to Second Modification)

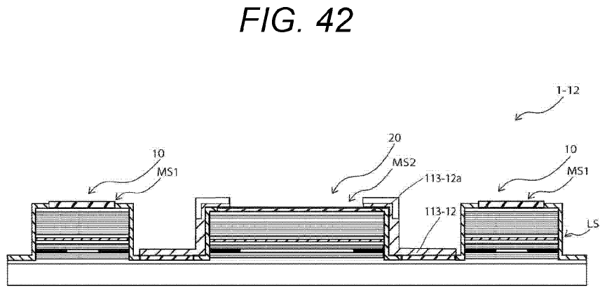

In the surface emitting laser apparatus 1-12 according to the second modification, as illustrated in FIG. 42, the position of the degassing unit 113-12a provided in the conductive layer 113-12 corresponds to the position of the degassing unit 113-2a in the surface emitting laser apparatus 1-2 according to the second example illustrated in FIGS. 14 to 16.

The degassing unit 113-12a is a thin film composed only of a base layer of the conductive layer 113-12.

(Surface Emitting Laser Apparatus According to Third Modification)

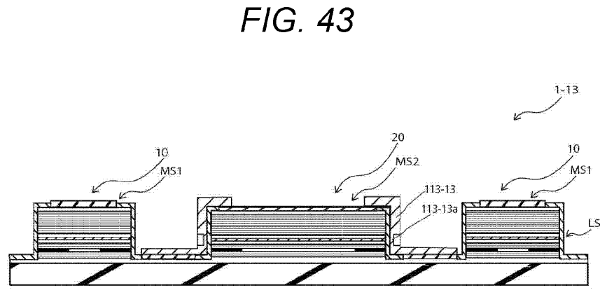

In the surface emitting laser apparatus 1-13 according to the third modification, as illustrated in FIG. 43, the position of the degassing unit 113-13a provided in the conductive layer 113-13 corresponds to the position of the degassing unit 113-3a in the surface emitting laser apparatus 1-3 according to the third example illustrated in FIGS. 17 to 19.

The degassing unit 113-13a is a thin film composed only of a base layer of the conductive layer 113-13.

(Surface Emitting Laser Apparatus According to Fourth Modification)

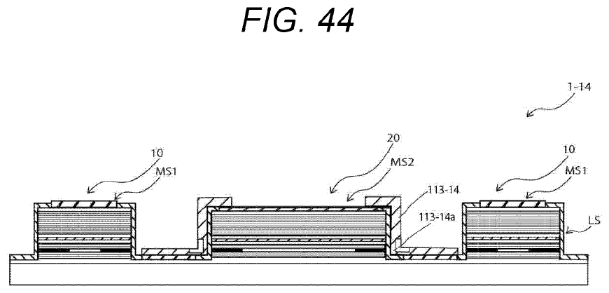

In the surface emitting laser apparatus 1-14 according to the fourth modification, as illustrated in FIG. 44, the position of the degassing unit 113-14a provided in the conductive layer 113-14 corresponds to the position of the degassing unit 113-4a in the surface emitting laser apparatus 1-4 according to the fourth example illustrated in FIGS. 20 to 22.

The degassing unit 113-14a is a thin film composed only of a base layer of the conductive layer 113-14.

(Surface Emitting Laser Apparatus According to Fifth Modification)

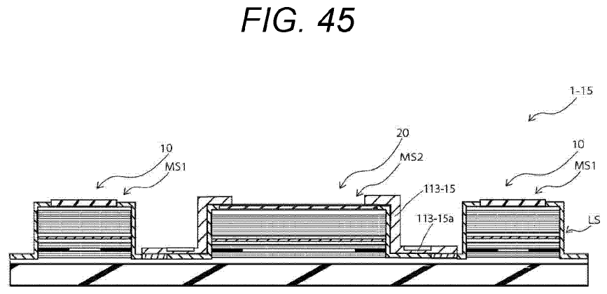

In the surface emitting laser apparatus 1-15 according to the fifth modification, as illustrated in FIG. 45, the position of the degassing unit 113-15a provided in the conductive layer 113-15 corresponds to the position of the degassing unit 113-5a in the surface emitting laser apparatus 1-5 according to the fifth example illustrated in FIGS. 23 to 25.

The degassing unit 113-15a is a thin film composed only of a base layer of the conductive layer 113-15.

(Surface Emitting Laser Apparatus According to Sixth Modification)

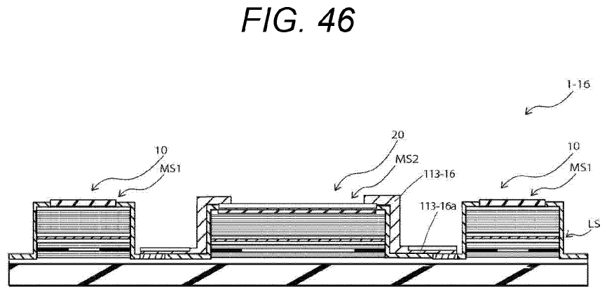

In the surface emitting laser apparatus 1-16 according to the sixth modification, as illustrated in FIG. 46, the position of the degassing unit 113-16a provided in the conductive layer 113-16 corresponds to the position of the degassing unit 113-6a in the surface emitting laser apparatus 1-6 according to the sixth example illustrated in FIGS. 26 to 28.

The degassing unit 113-16a is a thin film composed only of a base layer of the conductive layer 113-16.

(Surface Emitting Laser Apparatus According to Seventh Modification)

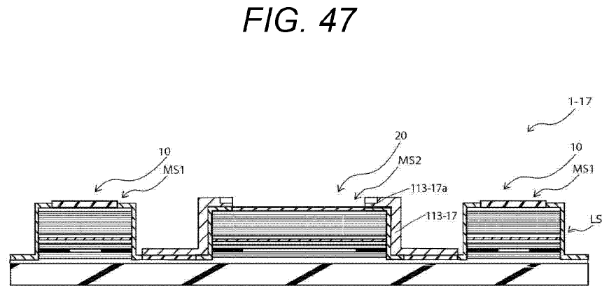

In the surface emitting laser apparatus 1-17 according to the seventh modification, as illustrated in FIG. 47, the position of the degassing unit 113-17a provided in the conductive layer 113-17 corresponds to the position of the degassing unit 113-7a in the surface emitting laser apparatus 1-7 according to the seventh example illustrated in FIGS. 29 to 31.

The degassing unit 113-17a is a thin film composed only of a base layer of the conductive layer 113-17.

(Surface Emitting Laser Apparatus According to Eighth Modification)

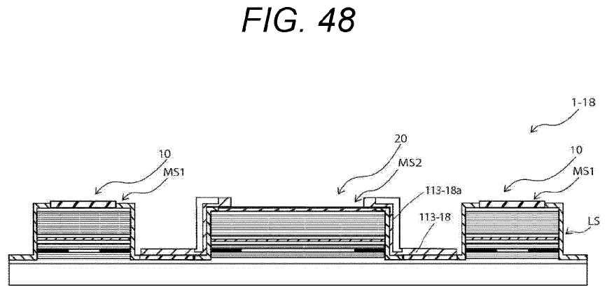

In the surface emitting laser apparatus 1-18 according to the eighth modification, as illustrated in FIG. 48, the position of the degassing unit 113-18a provided in the conductive layer 113-18 corresponds to the position of the degassing unit 113-8a in the surface emitting laser apparatus 1-8 according to the eighth example illustrated in FIGS. 32 to 34.

The degassing unit 113-18a is a thin film composed only of a base layer of the conductive layer 113-18.

(Surface Emitting Laser Apparatus According to Ninth Modification)

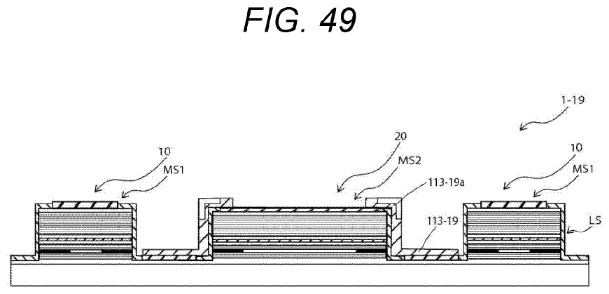

In the surface emitting laser apparatus 1-19 according to the ninth modification, as illustrated in FIG. 49, the position of the degassing unit 113-19a provided in the conductive layer 113-19 corresponds to the position of the degassing unit 113-9a in the surface emitting laser apparatus 1-9 according to the ninth example illustrated in FIGS. 35 to 37.

The degassing unit 113-19a is a thin film composed only of a base layer of the conductive layer 113-19.

(Surface Emitting Laser Apparatus According to Tenth Modification)

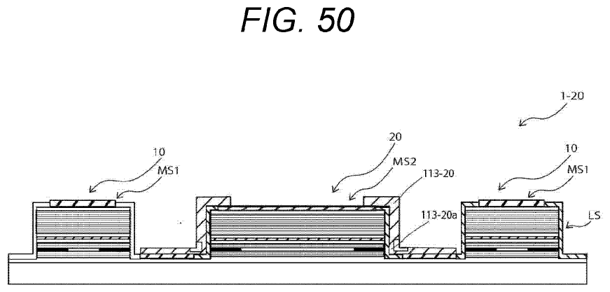

In the surface emitting laser apparatus 1-20 according to the tenth modification, as illustrated in FIG. 50, the position of the degassing unit 113-20a provided in the conductive layer 113-20 corresponds to the position of the degassing unit 113-10a in the surface emitting laser apparatus 1-10 according to the tenth example illustrated in FIGS. 38 to 40.

The degassing unit 113-20a is a thin film composed only of a base layer of the conductive layer 113-20.

### 8. <Another Modification of Embodiment of the Present Technology>

The number of the light emission units 10 and the electrode units 20 of the surface emitting laser apparatus 1 according to an embodiment of the present technology can be appropriately changed.

For example, the surface emitting laser apparatus 1 according to the present technology may include at least one set of a single light emission unit 10 and a single electrode unit 20.

The number of degassing units of the surface emitting laser apparatus 1 according to an embodiment of the present technology is not limited to four for one electrode unit 20, and may be one to three, or may be five or more.

The arrangement of the degassing units of the surface emitting laser apparatus 1 according to an embodiment of the present technology can be appropriately changed according to the shape and the like of the conductive layer and/or the electrode unit. For example, the plurality of degassing units may not necessarily be arranged at equal intervals.

For example, in the insulating layer 109 may be arranged between the first portion P1 and the stacked structure LS, between the second portion P2 and the near half part NH, and between the third portion P3 and the far half part FH.

For example, in a case where the degassing unit is provided at a position corresponding to the outer circumferential surface of the second oxidized constriction layer 103′ in a part of the second portion P2 covering the side surface of the near half part NH, the thickness of the insulating layer 109 between the second portion P2 and the near half part NH may be reduced as much as possible (for example, may be brought close to 0.1 μm as much as possible).

For example, in a case where the degassing unit is provided at a position corresponding to the outer circumferential surface of the second oxidized constriction layer 103′ in a part of the third portion P3 covering the side surface of the far half part FH, the thickness of the insulating layer 109 between the third portion P3 and the far half part FH may be reduced as much as possible (for example, may be brought close to 0.1 μm as much as possible).

For example, the thickness of the insulating layer may be less than 0.1 μm or greater than 2.0 μm.

The positions and forms (opening, cutout, and thin film) of the degassing units of the surface emitting laser apparatus 1 of the embodiments and modifications described above may be combined within a range not contradictory to each other.

For example, the degassing unit may be provided at least in a part of the second portion P2 covering the side surface of the near half part NH and a part of the third portion P3 covering the side surface of the far half part FH.

For example, the degassing unit is provided in a position corresponding to the outer circumferential surface of the second oxidized constriction layer 103′ in a part of the second portion P2 covering the side surface of the near half part NH and a part of the third portion covering the side surface of the far half part FH.

For example, the degassing unit may be provided at least in a part of the second portion P2 covering the upper surface of the near half part NH and a part of the third portion P3 covering the upper surface of the far half part FH.

For example, the degassing unit may be provided at least in a part of the second portion P2 covering the outer circumferential part of the upper surface of the near half part NH and a part of the third portion P3 covering the outer circumferential part of the upper surface of the far half part FH.

For example, the degassing unit may be provided at least in a part of the second portion P2 covering a corner part formed by the upper surface and the side surface of the near half part NH or a part of the third portion P3 covering a corner part formed by the upper surface and the side surface of the far half part FH.

For example, the degassing unit may be entirely provided in the conductive layer 113-1 at a position beyond 35 μm from the oxidized region 103b′ of the second oxidized constriction layer 103′.

A central interval between two adjacent light emission units 10 among the plurality of light emission units 10 may exceed 35 μm.

In each of the embodiments and modifications described above, the back surface emission type in which the light emission unit emits light to the back surface side of the substrate has been described as an example of the surface emitting laser apparatus 1 of the present technology, but the surface emitting laser apparatus of the present technology can also be applied to a surface emission type in which the light emission unit emits light from the top portion of the mesa structure.

In the embodiment and modifications described above, both the first and second multilayer film reflecting mirrors 102 and 107 are semiconductor multilayer film reflecting mirrors, but it is not limited thereto.

For example, the first multilayer film reflecting mirror 102 may be a semiconductor multilayer film reflecting mirror, and the second multilayer film reflecting mirror 107 may be a dielectric multilayer film reflecting mirror. The dielectric multilayer film reflecting mirror is also a kind of distributed Bragg reflecting mirror.

For example, the first multilayer film reflecting mirror 102 may be a dielectric multilayer film reflecting mirror, and the second multilayer film reflecting mirror 107 may be a semiconductor multilayer film reflecting mirror.

For example, both the first and second multilayer film reflecting mirrors 102 and 107 may be dielectric multilayer film reflecting mirrors.

In the surface emitting laser apparatus 1 according to the present technology, the first and second spacer layers 104, 106 are not necessarily provided.

In the surface emitting laser apparatus 1 according to the present technology, each oxidized constriction layer may be arranged inside the second multilayer film reflecting mirror 107.

In the surface emitting laser apparatus 1 according to the present technology, at least one of the first contact layer 101 or the second contact layer 108 is not necessarily provided.

### 9. <Example in which Surface Emitting Laser Apparatus is Applied to Distance Measuring Device>

Hereinafter, application examples of the surface emitting laser apparatus 1 according to each of the examples and modifications described above will be described.

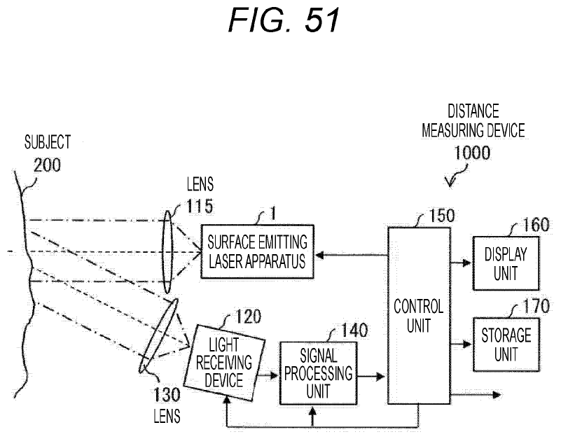

FIG. 51 illustrates an example of a schematic configuration of a distance measuring device 1000 including the surface emitting laser apparatus 1 as an example of an electronic device according to the present technology. The distance measuring device 1000 measures the distance to a subject 200 by a time of flight (TOF) method. The distance measuring device 1000 includes the surface emitting laser apparatus 1 as a light source. The distance measuring device 1000 includes, for example, the surface emitting laser apparatus 1, the light receiving device 120, lenses 115, 130, a signal processing unit 140, a control unit 150, a display unit 160, and a storage unit 170.

The light receiving device 120 detects light reflected by the subject 200. The lens 115 is a lens for collimating the light emitted from the surface emitting laser apparatus 1, and is a collimating lens. The lens 130 is a lens for condensing light reflected by the subject 200 and guiding the light to the light receiving device 120, and is a condenser lens.

The signal processing unit 140 is a circuit for generating a signal corresponding to a difference between the signal input from the light receiving device 120 and the reference signal input from the control unit 150. The control unit 150 includes, for example, a time to digital converter (TDC). The reference signal may be a signal input from the control unit 150, or may be an output signal of a detection unit that directly detects the output of the surface emitting laser apparatus 1. The control unit 150 is, for example, a processor that controls the surface emitting laser apparatus 1, the light receiving device 120, the signal processing unit 140, the display unit 160, and the storage unit 170. The control unit 150 is a circuit that measures the distance to the subject 200 on the basis of the signal generated by the signal processing unit 140. The control unit 150 generates a video signal for displaying information regarding the distance to the subject 200, and outputs the video signal to the display unit 160. The display unit 160 displays information regarding the distance to the subject 200 on the basis of the video signal input from the control unit 150. The control unit 150 stores information regarding the distance to the subject 200 in the storage unit 170.

In the present application example, the surface emitting laser apparatus 1 is applied to the distance measuring device 1000.

### 10. <Example in which Distance Measuring Device is Mounted on Moving Body>

### Application Example 1

The technology (the present technology) according to the present disclosure can be applied to various products. For example, the technology according to the present disclosure may be realized as a device mounted on any type of mobile body such as a car, electric vehicle, hybrid electric vehicle, motorcycle, bicycle, personal mobility, airplane, drone, ship, or robot.

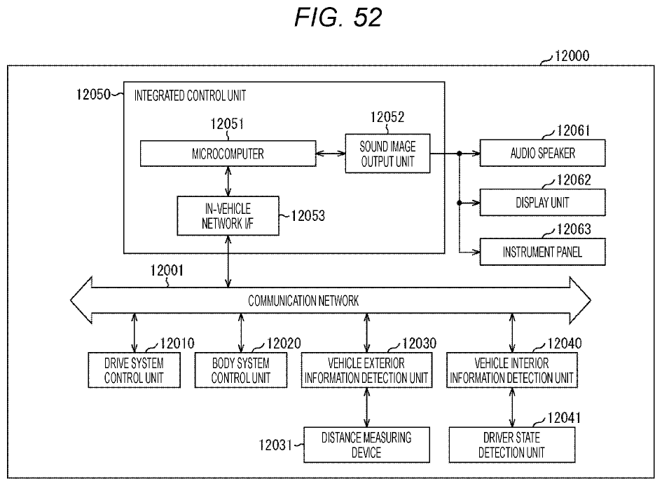

FIG. 52 is a block diagram showing a schematic configuration example of a vehicle control system which is an example of a mobile body control system to which the technology according to the present disclosure can be applied.

The vehicle control system 12000 includes a plurality of electronic control units connected via a communication network 12001. In the example shown in FIG. 52, the vehicle control system 12000 includes a drive system control unit 12010, a body system control unit 12020, a vehicle exterior information detection unit 12030, a vehicle interior information detection unit 12040, and an integrated control unit 12050. Furthermore, as a functional configuration of the integrated control unit 12050, a microcomputer 12051, a sound image output unit 12052, and an in-vehicle network interface (I/F) 12053 are illustrated.

The drive system control unit 12010 controls the operation of devices related to the drive system of the vehicle according to various programs. For example, the drive system control unit 12010 functions as a control device for a driving force generating device for generating a driving force of a vehicle such as an internal combustion engine or a driving motor, a driving force transmitting mechanism for transmitting a driving force to the wheels, a steering mechanism that adjusts steering of a vehicle, a braking device that generates a braking force of a vehicle, or the like.

The body system control unit 12020 controls the operation of various devices equipped in a vehicle body according to various programs. For example, the body system control unit 12020 functions as a control device for a keyless entry system, a smart key system, a power window device, or various lamps such as a head lamp, a back lamp, a brake lamp, a turn indicator, or a fog lamp. In this case, a radio wave transmitted from a portable device that substitutes for a key or a signal of various switches may be input to the body system control unit 12020. The body system control unit 12020 receives the input of these radio waves or signals and controls a door lock device, a power window device, a lamp, or the like of the vehicle.

The vehicle exterior information detection unit 12030 detects information outside the vehicle on which the vehicle control system 12000 is mounted. For example, a distance measuring device 12031 is connected to the vehicle exterior information detection unit 12030. The distance measuring device 12031 includes the above-described distance measuring device 1000. The vehicle exterior information detection unit 12030 causes the distance measuring device 12031 to measure a distance to an object outside the vehicle (subject 200), and acquires distance data obtained by the measurement. The vehicle exterior information detection unit 12030 may perform object detection processing of a person, a vehicle, an obstacle, a sign, or the like on the basis of the acquired distance data.

The vehicle interior information detection unit 12040 detects information inside the vehicle. For example, a driver state detection unit 12041 that detects the state of the driver is connected to the vehicle interior information detection unit 12040. The driver state detection unit 12041 includes, for example, a camera that images the driver, and the vehicle interior information detection unit 12040 may calculate the degree of fatigue or degree of concentration of the driver on the basis of the detection information input from the driver state detection unit 12041, or may determine whether or not the driver is dozing off.

The microcomputer 12051 can calculate a control target value of the driving force generating device, the steering mechanism, or the braking device on the basis of the information inside and outside of the vehicle acquired by the vehicle exterior information detection unit 12030 or the vehicle interior information detection unit 12040, and can output a control command to the drive system control unit 12010. For example, the microcomputer 12051 can perform cooperative control for the purpose of realization of the function of advanced driver assistance system (ADAS) including collision avoidance or impact mitigation of the vehicle, follow-up running based on the inter-vehicle distance, vehicle speed maintenance running, vehicle collision warning, vehicle lane departure warning, or the like.

Furthermore, the microcomputer 12051 controls the driving force generating device, the steering mechanism, the braking device, or the like on the basis of the information regarding the surroundings of the vehicle acquired by the vehicle exterior information detection unit 12030 or the vehicle interior information detection unit 12040, so that the microcomputer 12051 can perform cooperative control for the purpose of, for example, automated driving in which a vehicle autonomously runs without depending on the operation of the driver.

Furthermore, the microcomputer 12051 can output a control command to the body system control unit 12020 on the basis of the vehicle exterior information acquired by the vehicle exterior information detection unit 12030. For example, the microcomputer 12051 can control the headlamp according to the position of the preceding vehicle or the oncoming vehicle detected by the vehicle exterior information detection unit 12030, and perform cooperative control for the purpose of antiglare such as switching the high beam to low beam.

The sound image output unit 12052 transmits at least one of sound or image output signals to an output device capable of visually or audibly notifying the occupant of the vehicle or the outside of the vehicle, of information. In the example of FIG. 52, as an output device, an audio speaker 12061, a display unit 12062, and an instrument panel 12063 are illustrated. The display unit 12062 may include at least one of an on-board display or a head-up display, for example.

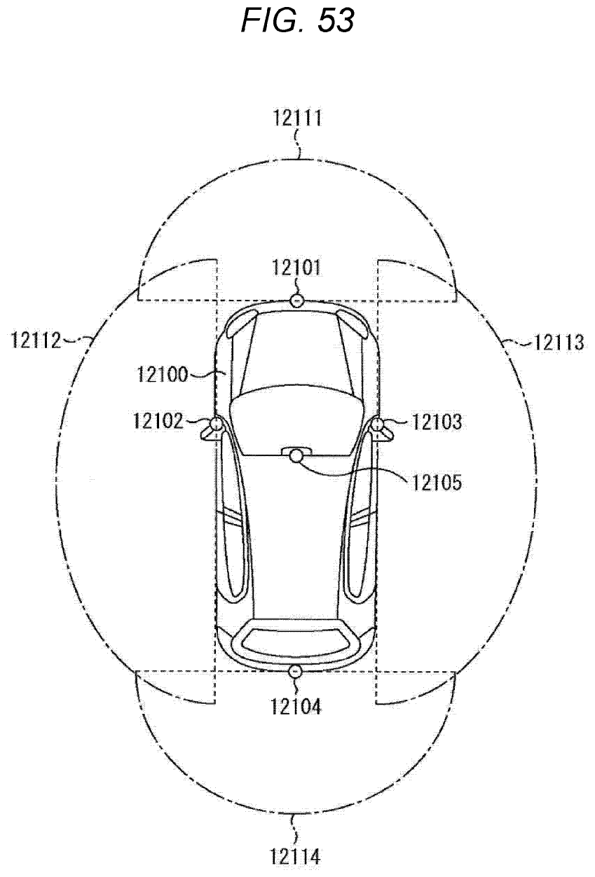

FIG. 53 is a diagram showing an example of an installation position of the distance measuring device 12031.

In FIG. 53, a vehicle 12100 includes distance measuring devices 12101, 12102, 12103, 12104, 12105 as the distance measuring device 12031.

For example, the distance measuring devices 12101, 12102, 12103, 12104, 12105 are provided at positions such as the front nose, the side mirror, the rear bumper, the back door, and the upper portion of the windshield in the vehicle compartment of the vehicle 12100. The distance measuring device 12101 included in the front nose and the distance measuring device 12105 included in the upper portion of the windshield in the vehicle compartment mainly acquire data of the forward of the vehicle 12100. The distance measuring devices 12102, 12103 provided in the side mirror mainly acquire data of the side of the vehicle 12100. The distance measuring device 12104 included in the rear bumper or the back door mainly acquires data of the rearward of the vehicle 12100. The data of the forward acquired by the distance measuring devices 12101 and 12105 are mainly used for detection of a preceding vehicle, a pedestrian, an obstacle, a traffic signal, a traffic sign, or the like.

Note that FIG. 53 shows an example of the detection range of the distance measuring devices 12101 to 12104. A detection range 12111 indicates a detection range of the distance measuring device 12101 provided in the front nose, detection ranges 12112 and 12113 indicate a detection range of the distance measuring devices 12102 and 12103 provided in the side mirror, respectively, and a detection range 12114 indicates a detection range of the distance measuring device 12104 provided in the rear bumper or the back door.

For example, the microcomputer 12051 obtains the distance to each three-dimensional object within the detection range 12111 to 12114 and the temporal change of the distance (relative speed with respect to the vehicle 12100), on the basis of the distance data obtained from the distance measuring devices 12101 to 12104, so that the microcomputer 12051 can extract a three-dimensional object that is the closest on the traveling path of the vehicle 12100 and runs at a predetermined speed (for example, 0 km/h or more) in substantially the same direction as that of the vehicle 12100, as a preceding vehicle. Moreover, the microcomputer 12051 can set an inter-vehicle distance to be secured in front of the preceding vehicle, and can perform automatic brake control (including follow-up stop control), automatic acceleration control (including follow-up start control), or the like. In such a manner, it is possible to perform cooperative control for the purpose of automated driving or the like that autonomously runs without depending on the operation of the driver.

For example, on the basis of the distance data obtained from the distance measuring devices 12101 to 12104, the microcomputer 12051 can classify three-dimensional object data on the three-dimensional object into other three-dimensional objects such as a two-wheeled vehicle, a regular vehicle, a large vehicle, a pedestrian, a telephone pole, and the like, and extract the result to use the result for automatic avoidance of obstacles. For example, the microcomputer 12051 identifies an obstacle in the vicinity of the vehicle 12100 as an obstacle that the driver of the vehicle 12100 can see and an obstacle that is difficult to see. Then, the microcomputer 12051 determines the collision risk indicating the risk of collision with each obstacle, and when the collision risk is equal to or higher than a set value and there is a possibility of collision, the microcomputer 12051 can output an alarm to the driver via the audio speaker 12061 and the display unit 12062 or perform forced deceleration or avoiding steering via the drive system control unit 12010, so as to perform driving assistance for collision avoidance.

An example of the moving body control system to which the technology according to the present disclosure can be applied has been described above. The technology according to the present disclosure can be applied to the distance measuring device 12031 in the above-described configuration.

The surface emitting laser apparatus 1 according to the present technology may be achieved as a light source of a device (for example, a laser printer, a laser copier, a projector, a head-mounted display, a head-up display, or the like) that forms or displays an image by laser light.

In each of the examples and the modifications described above, the specific numerical values, shapes, materials, structures, layer configurations, and the like described are merely examples, and it is not limited thereto.

Furthermore, the present technology can also adopt the following configuration.
(1) A surface emitting laser apparatus including:
a stacked structure having at least one light emission unit including a first oxidized constriction layer and an electrode unit including a second oxidized constriction layer at different positions in an in-plane direction; and
a conductive layer that makes the light emission unit and the electrode unit conductive with each other,
in which the conductive layer includes, in the stacked structure,
a first portion covering a region between the light emission unit and the electrode unit,
a second portion covering a near half part of the electrode unit, the near half part being relatively close to the light emission unit, and
a third portion covering a far half part of the electrode unit, the far half part being relatively far from the light emission unit, and
a degassing unit is provided in the first portion and/or the second portion and the third portion.
(2) The surface emitting laser apparatus according to (1), in which the degassing unit is an opening, a notch, or a thin film.
(3) The surface emitting laser apparatus according to (1) or (2), further including an insulating layer arranged between the first portion and the stacked structure and/or between the second portion and the near half part and between the third portion and the far half part.
(4) The surface emitting laser apparatus according to (3), in which a thickness of the insulating layer is equal to or greater than 0.1 μm and equal to or less than 2.0 μm.
(5) The surface emitting laser apparatus according to any one of (1) to (4), in which the degassing unit is provided at least in a part of the second portion covering a side surface of the near half part and/or a part of the third portion covering a side surface of the far half part.
(6) The surface emitting laser apparatus according to (1), in which the degassing unit is provided at least in a position in a part of the second portion covering a side surface of the near half part and/or a part of the third portion covering a side surface of the far half part, the position corresponding to an outer circumferential surface of the second oxidized constriction layer.
(7) The surface emitting laser apparatus according to any one of (1) to (6), in which the degassing unit is provided at least in a part of the second portion covering an upper surface of the near half part and/or a part of the third portion covering an upper surface of the far half part.
(8) The surface emitting laser apparatus according to any one of (1) to (7), in which the degassing unit is provided at least in a part of the second portion covering an outer circumferential part of an upper surface of the near half part and/or a part of the third portion covering an outer circumferential part of an upper surface of the far half part.
(9) The surface emitting laser apparatus according to any one of (1) to (8), in which the degassing unit is provided at least in a part of the second portion covering a corner part formed between an upper surface and a side surface of the near half part and/or a part of the third portion covering a corner part formed between an upper surface and a side surface of the far half part.
(10) The surface emitting laser apparatus according to any one of (1) to (9), in which the degassing unit is provided at least at a boundary between the first portion and the second portion.
(11) The surface emitting laser apparatus according to any one of (1) to (10), in which at least a part of the degassing unit is provided at a position within 35 μm from an oxidized region of the second oxidized constriction layer in the conductive layer.
(12) The surface emitting laser apparatus according to any one of (1) to (11), in which at least one light emission unit is a plurality of light emission units, and the conductive layer makes each of at least two light emission units among the plurality of light emission units and the electrode unit conductive with each other.
(13) The surface emitting laser apparatus according to (12), in which the conductive layer covers a region between each of the plurality of light emission units and the electrode unit and an outer circumferential surface and an outer circumferential part of an upper surface of the electrode unit in the stacked structure.
(14) The surface emitting laser apparatus according to (12) or (13), in which a central interval between two adjacent light emission units among the plurality of light emission units is equal to or less than 35 μm.
(15) The surface emitting laser apparatus according to any one of (1) to (14), in which the light emission unit includes a first multilayer film reflecting mirror including the first oxidized constriction layer therein, a second multilayer film reflecting mirror, and an active layer arranged between the first and second multilayer film reflecting mirrors, and the electrode unit includes a first multilayer film reflecting mirror including the second oxidized constriction layer therein, a second multilayer film reflecting mirror, and an active layer arranged between the first and second multilayer film reflecting mirrors.
(16) The surface emitting laser according to (15), in which the light emission unit includes a substrate that is arranged on a side opposite to a side of the active layer with respect to the first multilayer film reflecting mirror and that is transparent to an oscillation wavelength of the light emission unit, and the light emission unit emits light to a back surface side of the substrate.
(17) An electronic device including the surface emitting laser apparatus according to any one of (1) to (16).
(18) A method for manufacturing a surface emitting laser apparatus, the method including:
a step of forming a stacked body by stacking a first multilayer film reflecting mirror including a selected oxidized layer therein, an active layer, and a second multilayer film reflecting mirror in this order on a substrate;
a step of etching the stacked body to form a first mesa including one part of the selected oxidized layer and a second mesa including another part of the selected oxidized layer;
a step of oxidizing the one part and the another part of the selected oxidized layer from side surfaces to form a stacked structure having a light emission unit including a first oxidized constriction layer and an electrode unit including a second oxidized constriction layer; and
a step of forming a conductive layer including a first portion covering a region between the light emission unit and the electrode unit of the stacked structure, a second portion covering a near half part of the electrode unit, the near half part being relatively close to the light emission unit, and a third portion covering a far half part of the electrode unit, the far half part being relatively far from the light emission unit,
in which, in the step of forming the conductive layer,
a degassing unit is formed in the first portion and/or the second portion and the third portion.
(19) The method for manufacturing the surface emitting laser apparatus according to (18), in which the degassing unit is an opening, a notch, or a thin film.
(20) The method for manufacturing the surface emitting laser apparatus according to (18) or (19), further including, after the step of forming the stacked structure and before the step of forming the conductive layer, a step of forming an insulating layer in a region between the light emission unit and the electrode unit and/or in the near half part and the far half part of the stacked structure.

### REFERENCE SIGNS LIST

1 (1-1 to 1-20) Surface emitting laser apparatus
10 (10-1 to 10-6) Light emission unit
20 Electrode unit
100 Substrate
102 First multilayer film reflecting mirror
103 First oxidized constriction layer
103′ Second oxidized constriction layer
103S Selected oxidized layer
105 Active layer
107 Second multilayer film reflecting mirror
109 Insulating layer
113-1 to 113-20 Conductive layer
113-1a to 113-20a Degassing unit
LS Stacked structure
NH Near half part
FH Far half part
P1 First portion
P2 Second portion
P3 Third portion

1. A surface emitting laser apparatus comprising:
a stacked structure having at least one light emission unit including a first oxidized constriction layer and an electrode unit including a second oxidized constriction layer at different positions in an in-plane direction; and
a conductive layer that makes the light emission unit and the electrode unit conductive with each other,
wherein the conductive layer includes, in the stacked structure,
a first portion covering a region between the light emission unit and the electrode unit,
a second portion covering a near half part of the electrode unit, the near half part being relatively close to the light emission unit, and
a third portion covering a far half part of the electrode unit, the far half part being relatively far from the light emission unit, and
a degassing unit is provided in the first portion and/or the second portion and the third portion.

2. The surface emitting laser apparatus according to claim 1,
wherein the degassing unit is an opening, a notch, or a thin film.

3. The surface emitting laser apparatus according to claim 1, further comprising an insulating layer arranged between the first portion and the stacked structure and/or between the second portion and the near half part, and between the third portion and the far half part.

4. The surface emitting laser apparatus according to claim 3, wherein a thickness of the insulating layer is equal to or greater than 0.1 μm and equal to or less than 2.0 μm.

5. The surface emitting laser apparatus according to claim 1, wherein the degassing unit is provided at least in a part of the second portion covering a side surface of the near half part and/or a part of the third portion covering a side surface of the far half part.

6. The surface emitting laser apparatus according to claim 1, wherein the degassing unit is provided at least in a position in a part of the second portion covering a side surface of the near half part and/or a part of the third portion covering a side surface of the far half part, the position corresponding to an outer circumferential surface of the second oxidized constriction layer.

7. The surface emitting laser apparatus according to claim 1, wherein the degassing unit is provided at least in a part of the second portion covering an upper surface of the near half part and/or a part of the third portion covering an upper surface of the far half part.

8. The surface emitting laser apparatus according to claim 1, wherein the degassing unit is provided at least in a part of the second portion covering an outer circumferential part of an upper surface of the near half part and/or a part of the third portion covering an outer circumferential part of an upper surface of the far half part.

9. The surface emitting laser apparatus according to claim 1, wherein the degassing unit is provided at least in a part of the second portion covering a corner part formed between an upper surface and a side surface of the near half part and/or a part of the third portion covering a corner part formed between an upper surface and a side surface of the far half part.

10. The surface emitting laser apparatus according to claim 1, wherein the degassing unit is provided at least at a boundary between the first portion and the second portion.

11. The surface emitting laser apparatus according to claim 1, wherein at least a part of the degassing unit is provided at a position within 35 μm from an oxidized region of the second oxidized constriction layer in the conductive layer.

12. The surface emitting laser apparatus according to claim 1,
wherein the at least one light emission unit is a plurality of light emission units, and
the conductive layer makes each of at least two light emission units among the plurality of light emission units and the electrode unit conductive with each other.

13. The surface emitting laser apparatus according to claim 12, wherein the conductive layer covers a region between each of the plurality of light emission units and the electrode unit and an outer circumferential surface and an outer circumferential part of an upper surface of the electrode unit in the stacked structure.

14. The surface emitting laser apparatus according to claim 12, wherein a central interval between two adjacent light emission units among the plurality of light emission units is equal to or less than 35 μm.

15. The surface emitting laser apparatus according to claim 1,
wherein the light emission unit includes
a first multilayer film reflecting mirror including the first oxidized constriction layer therein,
a second multilayer film reflecting mirror, and
an active layer arranged between the first and second multilayer film reflecting mirrors, and
the electrode unit includes
a first multilayer film reflecting mirror including the second oxidized constriction layer therein,
a second multilayer film reflecting mirror, and
an active layer arranged between the first and second multilayer film reflecting mirrors.

16. The surface emitting laser according to claim 15, wherein the light emission unit includes a substrate that is arranged on a side opposite to a side of the active layer with respect to the first multilayer film reflecting mirror and that is transparent to an oscillation wavelength of the light emission unit, and
the light emission unit emits light to a back surface side of the substrate.

17. An electronic device including the surface emitting laser apparatus according to claim 1.

18. A method for manufacturing a surface emitting laser apparatus, the method comprising:
a step of forming a stacked body by stacking a first multilayer film reflecting mirror including a selected oxidized layer therein, an active layer, and a second multilayer film reflecting mirror in this order on a substrate;
a step of etching the stacked body to form a first mesa including one part of the selected oxidized layer and a second mesa including another part of the selected oxidized layer;
a step of oxidizing the one part and the another part of the selected oxidized layer from side surfaces to form a stacked structure having a light emission unit including a first oxidized constriction layer and an electrode unit including a second oxidized constriction layer; and
a step of forming a conductive layer including a first portion covering a region between the light emission unit and the electrode unit of the stacked structure, a second portion covering a near half part of the electrode unit, the near half part being relatively close to the light emission unit, and a third portion covering a far half part of the electrode unit, the far half part being relatively far from the light emission unit,
wherein, in the step of forming the conductive layer,
a degassing unit is formed in the first portion and/or the second portion and the third portion.

19. The method for manufacturing the surface emitting laser apparatus according to claim 18, wherein the degassing unit is an opening, a notch, or a thin film.

20. The method for manufacturing the surface emitting laser apparatus according to claim 18, further comprising, after the step of forming the stacked structure and before the step of forming the conductive layer, a step of forming an insulating layer in a region between the light emission unit and the electrode unit and/or in the near half part and the far half part of the stacked structure.
